(19) United States
(12) Patent Application Publication
(10) Pub. No.: US 2025/0040445 A1
(43) Pub. Date: Jan. 30, 2025

(54) SPINTRONICS DEVICE, MAGNETIC MEMORY, ELECTRONIC APPARATUS, AND MANUFACTURING METHOD FOR SPINTRONICS DEVICE

(71) Applicant: KEIO UNIVERSITY, Minato-ku, Tokyo (JP)

(72) Inventor: Yukio NOZAKI, Yokohama-shi, Kanagawa (JP)

(21) Appl. No.: 18/716,903

(22) PCT Filed: Nov. 1, 2022
(86) PCT No.: PCT/JP2022/040902

§ 371 Date: Jun. 5, 2024

(30) Foreign Application Priority Data
Dec. 10, 2021 (JP) 2021-201018

(51) Int. Cl. H10N 50/85; H01F 10/32; H10B 61/00; H10N 50/01; H10N 50/10

(52) U.S. Cl. CPC H10N 50/85; H01F 10/3254; H10B 61/22; H10N 50/01; H10N 50/10

(57) ABSTRACT

A spintronics device is a spintronics device that generates a spin current, the device including: a metal layer; a semiconductor layer having a lower carrier mobility or a lower electrical conductivity than the metal layer; and a gradient layer located at a boundary between the metal layer and the semiconductor layer, and having a gradient in the carrier mobility or the electrical conductivity.

### TECHNICAL FIELD

The present disclosure relates to a spintronics device, a magnetic memory, an electronic apparatus, and a method for manufacturing a spintronics device. Priority is claimed on Japanese Patent Application No. 2021-201018, filed on Dec. 10, 2021, the entire content of which is incorporated herein by reference.

### BACKGROUND ART

Patent Literature 1 discloses a technology related to a spintronics device. The spintronics device includes a first conductive layer and a second conductive layer having a lower carrier mobility or a lower electrical conductance than the first conductive layer. A boundary region between the first conductive layer and the second conductive layer has a gradient in the carrier mobility or the electrical conductance, and a spin current is generated by a rotation of an electron velocity field caused by the gradient. Patent Literature 1 describes, as an example, that the first conductive layer mainly contains copper and the second conductive layer mainly contains copper oxide.

Non Patent Literatures 1 and 2 disclose research on spin diffusion motion resulting from the magnetization motion of a magnetic material. In addition, Non Patent Literatures 3 and 4 disclose research on a relativistic effect in which up spins and down spins scatter in opposite directions in a noble metal such as platinum (Pt).

### CITATION LIST

### Patent Literature

Patent Literature 1: International Publication WO 2020/050329

### Non Patent Literature

Non Patent Literature 1: Mizukami et al., “The study on ferromagnetic resonance linewidth for NM/80NiFe/NM (NM=Cu, Ta, Pd and Pt) films”, Japanese Journal of Applied Physics, 40(2A), p. 580, (2001)
Non Patent Literature 2: Urban et al., “Gilbert Damping in Single and Multilayer Ultrathin Films: Role of Interfaces in Nonlocal Spin Dynamics”, Physical Review Letters, Volume 87, 217204, (2001)
Non Patent Literature 3: Kato et al., “Observation of the spin Hall effect in semiconductors”, Science, Volume 306, pp. 1910-1913 (2004)
Non Patent Literature 4: Kimura et al., “Room-temperature reversible spin Hall effect”, Physical Review Letters, Volume 98, 156601 (2007)
Non Patent Literature 5: Chen et al., “Spin-torque and spin-Hall nano-oscillators”, Proceedings, IEEE, Volume 104, pp. 1919-1945 (2016)
Non Patent Literature 6: An et al., “Spin-torque generator engineered by natural oxidation of Cu” Nature Communications, 7, 13069 (2016)

### SUMMARY OF INVENTION

### Technical Problem

The spin current is a flow of spin angular momentum without electric charge, and can be widely used to control various spintronics devices. Since no electric charge is involved, no Joule heat is generated, and the energy consumption of an electronic device can be significantly reduced. Further, the spin current can exert torques on magnetization more efficiently than an Oersted magnetic field. The spin current has the potential to dramatically improve the performance of electronic devices such as a transistor, a random access memory, and a logical operation element that encounter the theoretical limit of improving performance through miniaturization.

The conventional spin current generation theory is based on spin orbit interaction (SOI) that exists in substances. The SOI is a phenomenon inherent to a substance, and is known to increase in a rare metal with a larger atomic number, such as platinum, tantalum, tungsten, or bismuth. For that reason, the selection of materials to be used is excessively limited, which is a factor that suppresses a further improvement in spin current intensity.

In addition, Patent Literature 1 describes that as the material of the first conductive layer, metals such as copper (Cu), aluminum (Al), iron (Fe), and platinum (Pt), conductive nitrides such as titanium nitride (TIN), conductive polymers such as polyacetylene, and semiconductors such as silicon (Si) can be used. Oxides of the material of the first conductive layer are provided as examples of the material of the second conductive layer. However, since oxides generally have a small electrical conductance and a large amount of electric current is released as Joule heat in devices such as a magnetic memory including the spintronics device, various problems such as an increase in electric power consumption and heat generation occur.

An object of the present disclosure is to provide a spintronics device, a magnetic memory, an electronic apparatus, and a method for manufacturing a spintronics device having a high electrical conductance and capable of generating a large spin current without excessively limiting the selection of materials to be used.

### Solution to Problem

A spintronics device according to one embodiment is a spintronics device that generates a spin current, the device including: a metal layer; a semiconductor layer having a lower carrier mobility or a lower electrical conductivity than the metal layer; and a gradient layer located at a boundary between the metal layer and the semiconductor layer, and having a gradient in the carrier mobility or the electrical conductivity.

When an electric voltage is applied to a region with a gradient in the carrier mobility or the electrical conductivity, electrons move while colliding with scatterers; however, a movement velocity or an electric current density of electrons moving in a region with a high carrier mobility or a high electrical conductivity becomes larger than a movement velocity or an electric current density of electrons moving in a region with a low carrier mobility or a low electrical conductivity. Namely, in a region with a gradient in the carrier mobility or the electrical conductivity, unlike usual materials in which the carrier mobility or the electrical conductivity is uniform, a non-uniform distribution occurs in the electron movement velocity or the electric current density. In this case, when attention is paid to a very small region within the region, it can be considered that the electron velocity field or the electric current field (vector field) rotates in the very small region due to a difference in electron movement velocity or electric current density. The magnitude of the rotation of the velocity field or the electric current field can also be understood as vorticity. Due to the rotation of the velocity field or the electric current field, an “angular momentum” exists in the flow of a plurality of electrons in the region. The angular momentum is converted into spins in one direction (up spins or down spins), and a state of equilibrium between the up spins and the down spins is disturbed, thereby causing a bias in the relative distribution of the up spins and the down spins. As a result, a spin current is generated in a direction that eliminates the bias in distribution.

According to the findings of the present inventors, for example, a large spin current as large as or more than that based on SOI can be generated through the above-described action. In addition, the above-described action is realized simply by forming a gradient in the carrier mobility or the electrical conductivity, and does not require a rare material such as a noble metal (for example, Pt) that generates SOI. Namely, by combining the metal layer made of any metal, for example, Al that exists abundantly in the earth's crust and a semiconductor layer made of any semiconductor, for example, Si that exists abundantly in the earth's crust, the gradient layer having a gradient in the carrier mobility or the electrical conductivity can be easily formed. In addition, the metal layer and the semiconductor layer have a larger electrical conductance than oxides, and the release of Joule heat can be reduced in a device such as a magnetic memory including the spintronics device. In such a manner, according to the spintronics device, it is possible to generate a large spin current while increasing the electrical conductance without excessively limiting the selection of materials to be used.

In the spintronics device, the metal layer may contain aluminum (Al). Alternatively, the metal layer may be an Al layer. Al is the third most abundant element after oxygen (O) and silicon (Si) among elements that exist in the earth's crust, and is the most abundant element among metal elements. In addition, Al has a relatively high electrical conductance among the metal elements. Therefore, it is possible to provide a sustainable spintronics device capable of reducing electric power consumption.

In the spintronics device, the semiconductor layer may contain Si. Alternatively, the semiconductor layer may be a Si layer. Si is the second most abundant element after oxygen (O) among the elements that exist in the earth's crust, and is the most abundant element among semiconductors. Therefore, it is possible to provide a sustainable spintronics device.

In the spintronics device, the metal layer may be an Al layer, the semiconductor layer may be a Si layer, and a thickness of the gradient layer may be 2.4 nm or less. According to experiments by the present inventors, by having such a thickness for the gradient layer, a larger spin current than a spin current generated by SOI can be generated.

In the spintronics device, the spin current may be generated by a rotation of an electron velocity field or an electric current field, which is caused by the gradient. Further, the spin current may be generated by an angular momentum due to the rotation of the electron velocity field or the electric current field. By these means, the spin current can be generated as described above.

A magnetic memory according to one embodiment includes any of the above spintronics devices. Therefore, it is possible to control the direction of magnetization while reducing electric power consumption without excessively limiting the selection of materials to be used.

A magnetic memory according to another embodiment includes a first ferromagnetic layer; a non-magnetic layer provided on the first ferromagnetic layer; a second ferromagnetic layer provided on the non-magnetic layer; a metal layer provided on the second ferromagnetic layer; a semiconductor layer having a lower carrier mobility or a lower electrical conductivity than the metal layer, and provided on the metal layer; and a gradient layer located at a boundary between the metal layer and the semiconductor layer, and having a gradient in the carrier mobility or the electrical conductivity. The magnetic memory stores information by controlling a direction of a magnetization of the second ferromagnetic layer using a spin current generated in the gradient layer. The magnetic memory has the configuration of the spintronics device described above. Therefore, it is possible to control the direction of magnetization while reducing electric power consumption without excessively limiting the selection of materials to be used.

An electronic apparatus according to one embodiment is an electronic apparatus on which one or more magnetic memories are mounted. The electronic apparatus has the configuration of the spintronics device described above. Therefore, it is possible to control the direction of magnetization while reducing electric power consumption without excessively limiting the selection of materials to be used.

A method for manufacturing a spintronics device according to one embodiment is a method for manufacturing any of the above spintronics devices, the method including: a step of forming a first layer by depositing the same material as the metal layer on the semiconductor layer through sputtering; a step of forming a second layer by depositing the same material as the semiconductor layer on the first layer through sputtering; and a step of forming the metal layer on the second layer.

In the manufacturing method, the gradient layer is formed by mixing atoms of the first layer and the second layer in sputtering. The thickness of the gradient layer depends on the total thickness of the first layer and the second layer. Therefore, the gradient layer of any thickness can be easily formed. In addition, the gradient layer can also be formed, for example, by depositing the material of the semiconductor layer and the material of the metal layer at the same time, and gradually changing the deposition ratio thereof; however, in that case, a target made of the material of the semiconductor layer and a target made of the material of the metal layer should be installed in a sputtering apparatus at the same time, so that the size of the sputtering apparatus is increased. In the manufacturing method, since the material of the semiconductor layer and the material of the metal layer are alternately deposited, the target made of the material of the semiconductor layer and the target made of the material of the metal layer may be alternately installed in the sputtering apparatus. Therefore, the number of the targets installed in the sputtering apparatus at the same time can be reduced, and the sputtering apparatus can be downsized.

### Advantageous Effects of Invention

According to the present disclosure, it is possible to provide the spintronics device, the magnetic memory, the electronic apparatus, and the method for manufacturing a spintronics device capable of generating a large spin current while reducing electric power consumption without excessively limiting the selection of materials to be used.

### BRIEF DESCRIPTION OF DRAWINGS

FIG. 1 is a perspective view showing a configuration of a spintronics device according to a first embodiment of the present disclosure.

FIG. 2 Portions (a) to (e) in FIG. 2 are schematic views showing a method for manufacturing a spintronics device when materials constituting a semiconductor layer and a metal layer form a non-solid solution system.

FIG. 3 Portions (a) to (d) in FIG. 3 are schematic views showing a method for manufacturing a spintronics device when materials constituting the semiconductor layer and the metal layer form a solid solution system.

FIG. 4 is a graph showing a change in the electrical conductivity of a device 1 in a stacking direction.

FIG. 5 Portions (a) and (b) in FIG. 5 are schematic views showing the velocity of electrons moving inside the spintronics device or an electric current density when an electric voltage is applied in a direction intersecting the stacking direction.

FIG. 6 is a schematic view showing a spin current generation mechanism by a Rayleigh wave as a reference example.

FIG. 7 is a view showing the structure of a sample used in an experiment.

FIG. 8 Portions (a) and (b) in FIG. 8 are HAADF-STEM images showing the layer structure of a manufactured sample. A portion (c) in FIG. 8 is a graph showing the distributions of the atomic concentrations of Si and Al obtained by performing energy dispersive X-ray spectroscopy on a region inside a broken line frame in FIG. 8(b).

FIG. 9 Portions (a) and (b) in FIG. 9 are HAADF-STEM images showing the layer structure of a manufactured sample. A portion (c) in FIG. 9 is a graph showing the distributions of the atomic concentrations of Si and Al obtained by performing energy dispersive X-ray spectroscopy on a region inside a broken line frame in the portion (b) in FIG. 9

FIG. 10 Portions (a) and (b) in FIG. 10 are HAADF-STEM images showing the layer structure of a manufactured sample. A portion (c) in FIG. 10 is a graph showing the distributions of the atomic concentrations of Si and Al obtained by performing energy dispersive X-ray spectroscopy on a region inside a broken line frame in the portion (b) in FIG. 10.

FIG. 11 Portions (a) and (b) in FIG. 11 are nano-beam electron diffraction (NBED) patterns for the semiconductor layer (Si layer) and the metal layer (Al layer) each having a thickness of 10 nm, respectively.

FIG. 12 is a view for describing the principle of ST-FMR measurement.

FIG. 13 is a view showing a circuit used for ST-FMR measurement.

FIG. 14 A portion (a) in FIG. 14 is a graph showing an ST-FMR spectrum of a sample in which the total thickness of a first layer and a second layer is 0.5 nm. A portion (b) in FIG. 14 shows symmetric and antisymmetric Lorentz function components included in the graph shown in the portion (a) in FIG. 14.

FIG. 15 is a graph showing a relationship between an obtained spin torque efficiency and the total thickness of the first layer and the second layer.

FIG. 16 A portion (a) in FIG. 16 is a graph showing a relationship between the symmetric Lorentz function component and an application angle of an external magnetic field. A portion (b) in FIG. 16 is a graph showing a relationship between the antisymmetric Lorentz function component and the application angle of the external magnetic field.

FIG. 17 is a graph showing a relationship between the spin torque efficiency and both a damping-like torque efficiency and a field-like torque efficiency.

FIG. 18 is a graph showing a relationship between a conversion efficiency from a spin current to an electric current and the damping-like torque efficiency.

FIG. 19 is a graph showing a relationship between the total thickness of the first layer and the second layer and the electrical conductivity of the samples.

FIG. 20 is a graph showing a relationship between the electrical conductance and a product of the damping-like torque efficiency and the electrical conductance for each sample.

FIG. 21 is a perspective view showing a configuration of a magnetic memory according to a second embodiment of the present disclosure.

FIG. 22 Portions (a) and (b) in FIG. 22 are cross-sectional views showing a configuration of a memory cell.

FIG. 23 is a graph that plots various materials according to a spin hall conductivity and an electrical conductivity.

FIG. 24 A portion (a) in FIG. 24 is a view schematically showing an atomic structure of the semiconductor layer, the metal layer, and a gradient layer. A portion (b) in FIG. 24 is a graph showing a change in electrical conductivity in a thickness direction.

### DESCRIPTION OF EMBODIMENTS

Hereinafter, embodiments of a spintronics device, a magnetic memory, an electronic apparatus, and a method for manufacturing a spintronics device according to the present disclosure will be described in detail with reference to the accompanying drawings. Incidentally, in the description of the drawings, the same components are denoted by the same reference signs, and duplicate descriptions will be omitted.

### First Embodiment

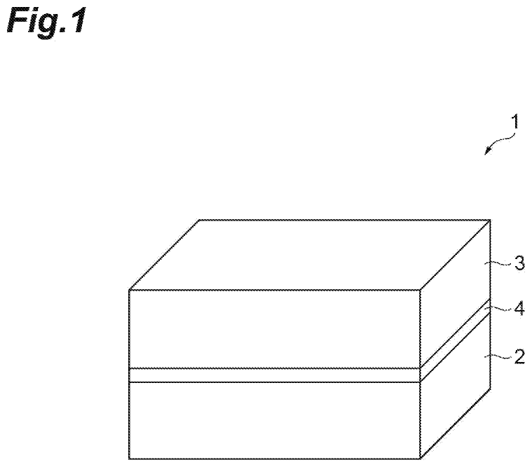

FIG. 1 is a perspective view showing a configuration of a spintronics device 1 (hereinafter, simply referred to as the device 1) according to a first embodiment of the present disclosure. As shown in FIG. 1, the device 1 includes a semiconductor layer 2, a metal layer 3, and a gradient layer 4. A carrier mobility (hereinafter, may be simply referred to as mobility) or electrical conductivity of a material constituting the semiconductor layer 2 is lower than a mobility or electrical conductance of a material constituting the metal layer 3. The semiconductor layer 2 contains a semiconductor such as silicon (Si), germanium (Ge), gallium arsenide (GaAs), or indium phosphide (InP), or a combination thereof. The semiconductor layer 2 may be made of any of these semiconductors or a combination of these semiconductors. In one example, the semiconductor layer 2 contains Si or is a Si layer. A thickness of the semiconductor layer 2 is, for example, in a range of 0.1 nm to 1000 nm.

The metal layer 3 contains any of metals such as copper (Cu), aluminum (Al), iron (Fe), platinum (Pt), gold (Au), and silver (Ag), or a combination of at least two of these metals (for example, alloy). The metal layer 3 may made of any of these metals or a combination of at least two of these metals. In one example, the metal layer 3 contains Al or is an Al layer. A thickness of the metal layer 3 is, for example, in a range of 0.1 nm to 1000 nm. The metal layer 3 can be formed on the semiconductor layer 2, for example, by sputtering or the like.

The gradient layer 4 is a layered region that exists at the boundary between the semiconductor layer 2 and the metal layer 3. The semiconductor layer 2 and the metal layer 3 are in contact with each other when observed macroscopically; however, the gradient layer 4 with a slight thickness exists between the semiconductor layer 2 and the metal layer 3 when observed microscopically. A thickness of the gradient layer 4 is, for example, larger than 0 nm and less than or equal to 100 nm. When the gradient layer 4 is made of Si and Al, the thickness of the gradient layer 4 is, for example, larger than 0 nm and less than or equal to 2.4 nm. The thickness of the gradient layer 4 may be a value very close to zero, for example, a few angstroms. In the gradient layer 4, the constituent material of the metal layer 3 and the constituent material of the semiconductor layer 2 are mixed. In the gradient layer 4, the closer the gradient layer 4 is to the interface with the metal layer 3, the larger the proportion of the constituent material of the metal layer 3 becomes, and the closer the gradient layer 4 is to the interface with the semiconductor layer 2, the larger the proportion of the constituent material of the semiconductor layer 2 becomes.

The materials constituting the semiconductor layer 2 and the metal layer 3 may form a non-solid solution system. From such a viewpoint, when the semiconductor layer 2 mainly contains Si, the metal layer 3 may mainly contain any of Al, Ag, and Au, or a combination of at least two of these metals. When the materials constituting the semiconductor layer 2 and the metal layer 3 form a non-solid solution system, atoms constituting the semiconductor layer 2 and the metal layer 3 are less likely to diffuse into each other. Therefore, the thickness of the gradient layer 4 and a change over time in the composition distribution in a thickness direction of the gradient layer 4 can be suppressed to a low level. Particularly, when a device such as a magnetic memory including the device 1 is manufactured, heat treatment may be performed at a temperature of several hundreds ° C. to a thousand and several hundreds ° C. in the manufacturing process of the device. Even in such a case, when the materials constituting the semiconductor layer 2 and the metal layer 3 form a non-solid solution system, the thickness of the gradient layer 4 and a change over time in the composition distribution in the thickness direction of the gradient layer 4 can be suppressed to a low level. Therefore, for example, the characteristics of the device 1 such as a spin current generation efficiency can be maintained for a long period of time.

Alternatively, the materials constituting the semiconductor layer 2 and the metal layer 3 may form a solid solution system. From such a viewpoint, when the semiconductor layer 2 mainly contains Si, the metal layer 3 may contain any of Cu, chromium (Cr), Fe, nickel (Ni), Pt, tantalum (Ta), titanium (Ti), and tungsten (W) or a combination of at least two of these metals. When the materials constituting the semiconductor layer 2 and the metal layer 3 form a solid solution system, atoms constituting the semiconductor layer 2 and the metal layer 3 are likely to diffuse into each other. Therefore, the gradient layer 4 can be easily formed by the diffusion of atoms between the semiconductor layer 2 and the metal layer 3 due to, for example, heat treatment or the like.

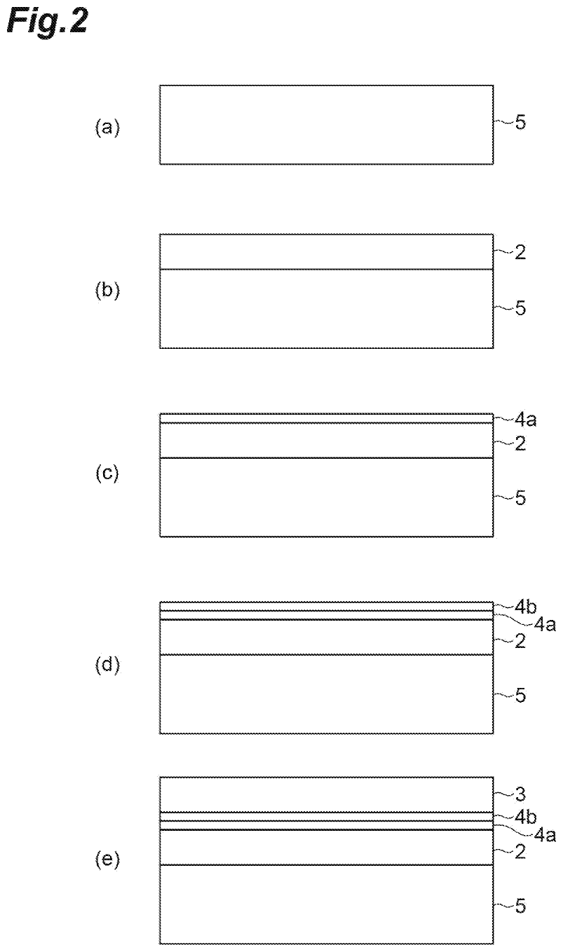

Portions (a) to (e) in FIG. 2 are schematic views showing a method for manufacturing the device 1 when the materials constituting the semiconductor layer 2 and the metal layer 3 form a non-solid solution system. First, as shown in the portion (a) in FIG. 2, a substrate 5 is prepared. As the substrate 5, various substrates, for example, a surface-oxidized Si substrate can be used. Next, the substrate 5 is installed in a sputtering apparatus, and a first target made of the same material as the semiconductor layer 2 is installed in the sputtering apparatus. Then, as shown in the portion (b) in FIG. 2, the semiconductor layer 2 is formed by depositing the material of the semiconductor layer 2 on the substrate 5 through sputtering. A deposition thickness of the semiconductor layer 2 is, for example, 10 nm or more. Alternatively, the deposition thickness of the semiconductor layer 2 may be larger than 0 nm and less than 10 nm. Subsequently, instead of the first target, a second target made of the same material as the metal layer 3 is installed in the sputtering apparatus, and as shown in the portion (c) in FIG. 2, a first layer 4a is formed by depositing the same material as the metal layer 3 on the semiconductor layer 2 through sputtering. A deposition thickness of the first layer 4a is, for example, 0.25 nm or more and 1.0 nm or less. Alternatively, the deposition thickness of the first layer 4a may be larger than 0 nm and less than 0.25 nm. Subsequently, instead of the second target, the first target is installed in the sputtering apparatus again, and as shown in the portion (d) in FIG. 2, a second layer 4b is formed by depositing the same material as the semiconductor layer 2 on the first layer 4a through sputtering. A deposition thickness of the second layer 4b is, for example, 0.25 nm or more and 1.0 nm or less. Alternatively, the deposition thickness of the first layer 4a may be larger than 0 nm and less than 0.25 nm. In one example, the deposition thickness of the second layer 4b is equal to the deposition thickness of the first layer 4a. Thereafter, instead of the first target, the second target is installed in the sputtering apparatus again, and as shown in the portion (e) in FIG. 2, the metal layer 3 is formed by depositing the material of the metal layer 3 on the second layer 4b through sputtering. A deposition thickness of the metal layer 3 is, for example, 10 nm or more. Alternatively, the deposition thickness of the metal layer 3 may be larger than 0 nm and less than 10 nm.

When the first layer 4a, the second layer 4b, and the metal layer 3 are deposited by sputtering, material particles enter the surface of the substrate 5 with great force, so that due to the large kinetic energy of the particles, the particles are mixed with atoms of a foundation layer (the semiconductor layer 2 for the first layer 4a, the first layer 4a for the second layer 4b, and the second layer 4b for the metal layer 3). Therefore, the first layer 4a and the second layer 4b are not neatly layered, and a smooth gradient in a composition ratio between the constituent material of the semiconductor layer 2 and the constituent material of the metal layer 3 is formed between the semiconductor layer 2 and the metal layer 3. Accordingly, the mixing region between the semiconductor layer 2 and the metal layer 3 is increased, and the gradient layer 4 is formed. Incidentally, in this case, since the materials constituting the semiconductor layer 2 and the metal layer 3 form a non-solid solution system, the materials do not diffuse in a single atomic unit, and a lump in which a plurality of atoms of the constituent material of the semiconductor layer 2 are agglomerated and a lump in which a plurality of atoms of the constituent material of the metal layer 3 are agglomerated may be formed. The device 1 is manufactured through the above steps.

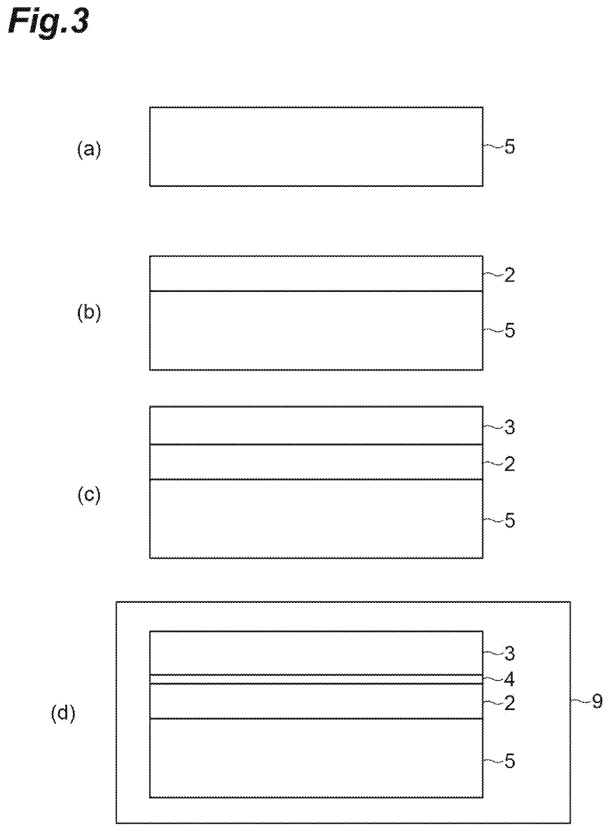

Portions (a) to (d) in FIG. 3 are schematic views showing a method for manufacturing the device 1 when the materials constituting the semiconductor layer 2 and the metal layer 3 form a solid solution system. First, as shown in the portion (a) in FIG. 3, the substrate 5 is prepared. Next, as shown in the portion (b) in FIG. 3, the substrate 5 is installed in a film forming apparatus, and the semiconductor layer 2 is film-formed on the substrate 5. A film thickness of the semiconductor layer 2 is, for example, 10 nm or more. Alternatively, the deposition thickness of the semiconductor layer 2 may be larger than 0 nm and less than 10 nm. Then, as shown in the portion (c) in FIG. 3, the metal layer 3 is film-formed on the semiconductor layer 2. A film thickness of the metal layer 3 is, for example, 10 nm or more. Alternatively, the deposition thickness of the metal layer 3 may be larger than 0 nm and less than 10 nm. The formation of these films can be performed, for example, by sputtering, chemical vapor deposition, or vacuum evaporation. Thereafter, as shown in the portion (d) in FIG. 3, the substrate 5 is installed in a heat treatment apparatus 9, and atoms at the interface between the semiconductor layer 2 and the metal layer 3 are diffused into each other by performing heat treatment, and the gradient layer 4 is formed. The device 1 is manufactured through the above steps. Incidentally, even when the materials constituting the semiconductor layer 2 and the metal layer 3 form a solid solution system, the method shown in the portions (a) to (e) in FIG. 2 may be used.

The substrate 5 used in each manufacturing method described above may be removed from the device 1 if necessary.

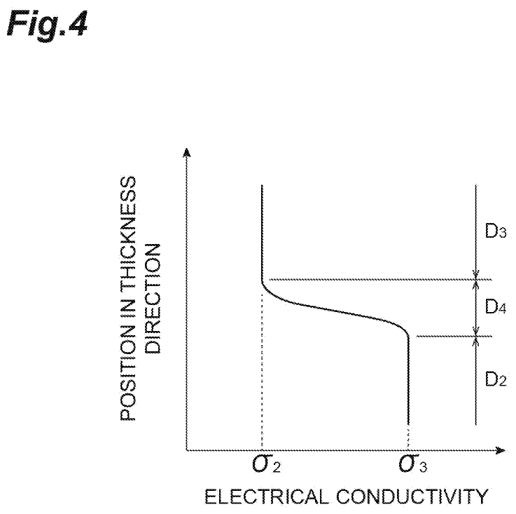

FIG. 4 is a graph showing a change in the electrical conductivity of the device 1 in a stacking direction. In FIG. 4, a range D₂ corresponds to the semiconductor layer 2, a range D₃ corresponds to the metal layer 3, and a range D₄ corresponds to the gradient layer 4.

As shown in FIG. 4, an electrical conductivity σ₂ of the material constituting the semiconductor layer 2 is lower than an electrical conductivity σ₃ of the material constituting the metal layer 3. The electrical conductivities σ₂ and σ₃ are, for example, larger than 0 and less than or equal to 100 MSm⁻¹. The lower limit value of the ratio of these electrical conductivities (σ₃/σ₂) is, for example, 10. Incidentally, the upper limit value of the ratio (σ₃/σ₂) is, for example, 100000, but may be larger than 100000 from the viewpoint of spin current generation. The electrical conductivity of the gradient layer 4 has a gradient, and changes continuously from the interface with the semiconductor layer 2 to the interface with the metal layer 3. The rate of change in electrical conductivity in the gradient layer 4 may or may not be constant in the thickness direction. For example, the rate of change in electrical conductivity may be larger in a region located intermediate between the semiconductor layer 2 and the metal layer 3 than in a region close to the semiconductor layer 2 and a region close to the metal layer 3. The change in electrical conductivity is due to a change in the proportions of the materials constituting the gradient layer 4.

In the above description, the electrical conductivity may be replaced with the carrier mobility. Namely, a carrier mobility μ₂ of the material constituting the semiconductor layer 2 is lower than a carrier mobility μ₃ of the material constituting the metal layer 3. The lower limit value of the ratio of these carrier mobilities (μ₃/μ₂) is, for example, 10. Incidentally, the upper limit value of the ratio (μ₃/μ₂) is, for example, 100000, but may be larger than 100000 from the viewpoint of spin current generation. The carrier mobility of the gradient layer 4 has a gradient, and changes continuously from the interface with the semiconductor layer 2 to the interface with the metal layer 3. The rate of change in carrier mobility in the gradient layer 4 may or may not be constant in the thickness direction. For example, the rate of change in carrier mobility may be larger in the region located between the semiconductor layer 2 and the metal layer 3 than in the region close to the semiconductor layer 2 and the region close to the metal layer 3. The change in carrier mobility is due to a change in the proportions of the materials constituting the gradient layer 4.

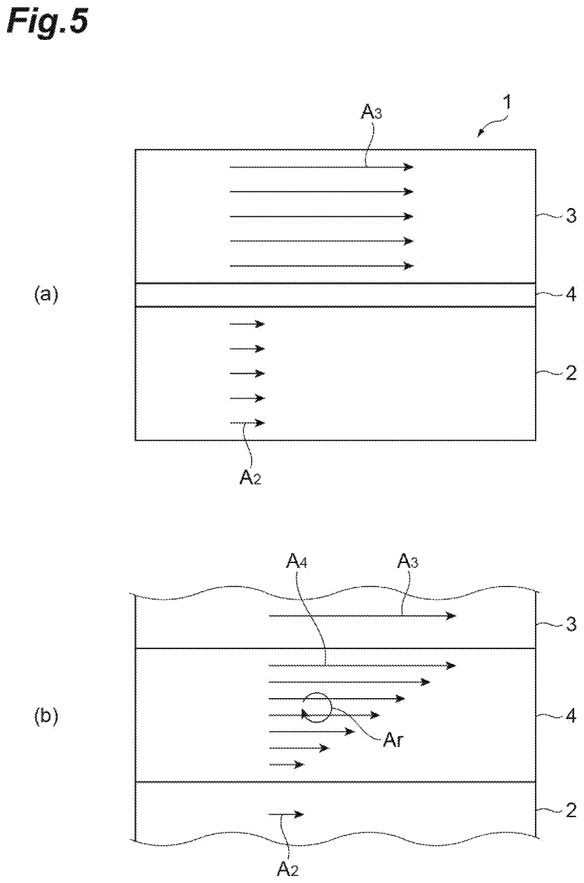

Portions (a) and (b) in FIG. 5 are schematic views showing the magnitude of an electric current density or the velocity of electrons moving inside the device 1, when an electric voltage is applied in a direction intersecting the stacking direction. The portion (a) in FIG. 5 shows the entirety of the device 1, and the portion (b) in FIG. 5 shows the vicinity of the gradient layer 4 in an enlarged manner. In the figures, arrow A₂ indicates the movement of electrons in the semiconductor layer 2, arrow A₃ indicates the movement of electrons in the metal layer 3, and arrow A₄ indicates the movement of electrons in the gradient layer 4. The length of each of arrows A₂ to A₅ represents an electron movement velocity or electric current density, and the longer the arrow is, the larger the electron movement velocity or electric current density is. Incidentally, when an electric voltage is applied to a material containing free electrons, each electron repeatedly accelerates and decelerates while colliding with scatterers in the material, and moves in a zigzag motion through the material in an electric voltage application direction. When this behavior is viewed on a large temporal and spatial scale, it can be understood that electron groups move uniformly in one direction. Arrows A₂ to A₄ in the portions (a) and (b) in FIG. 5 express the uniform movements of such electron groups.

An electric current density in the metal layer 3 having a high electrical conductivity becomes larger than an electric current density of electrons moving through the semiconductor layer 2 having a low electrical conductivity. In addition, a movement velocity of electrons moving through the metal layer 3 having a high carrier mobility is faster than a movement velocity of electrons moving through the semiconductor layer 2 having a low carrier mobility. Therefore, arrow A₃ is longer than arrow A₂. On the other hand, in the gradient layer 4, unlike the semiconductor layer 2 and the metal layer 3 in which the electrical conductivity or the carrier mobility is uniform, a non-uniform distribution occurs in the electric current density or electron movement velocity. In the present embodiment, the electrical conductivity or carrier mobility in the gradient layer 4 has a gradient, and the electrical conductivity or carrier mobility changes continuously such that the electrical conductivity or carrier mobility is large in the vicinity of the interface with the metal layer 3 and is small in the vicinity of the interface with the semiconductor layer 2. Therefore, as shown in the portion (b) in FIG. 5, the electric current density or electron movement velocity in the gradient layer 4 changes continuously such that the electric current density or electron movement velocity is large in the vicinity of the interface with the metal layer 3 and is small in the vicinity of the interface with the semiconductor layer 2. Incidentally, the rate of change in electric current density or electron movement velocity in the gradient layer 4 may or may not be constant in the thickness direction. For example, the rate of change in electric current density or electron movement velocity may be larger in the region located intermediate between the semiconductor layer 2 and the metal layer 3 than in the region close to the semiconductor layer 2 and the region close to the metal layer 3. Such a change in electric current density or electron movement velocity is also due to a change in the proportions of the materials constituting the gradient layer 4.

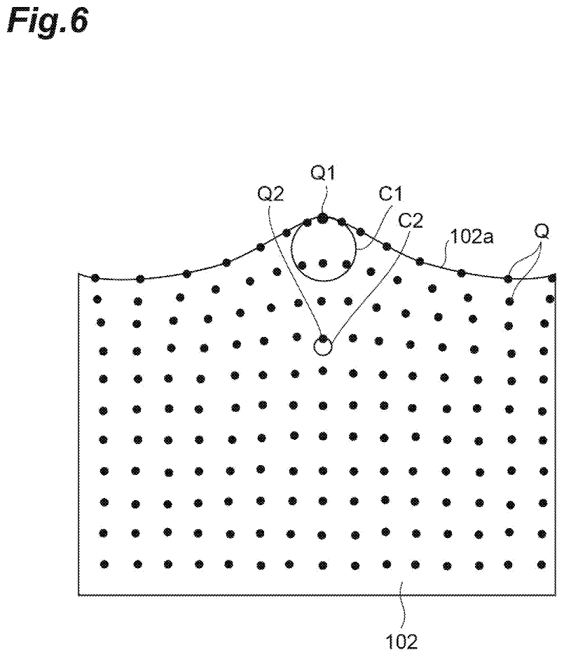

A spin current generation action in the device 1 will be described. FIG. 6 is a schematic view showing a spin current generation mechanism by a Rayleigh wave as a reference example. A Rayleigh wave is a type of sound wave, and is a phenomenon where elastic deformation of a solid propagates on the surface as a wave. When a pair of interdigitated electrodes are disposed to face each other on a surface of a piezoelectric body, and a high-frequency electric voltage is applied between these interdigitated electrodes, a Rayleigh wave is generated on the surface of the piezoelectric body. When a metal film 102 is formed in a traveling direction of a Rayleigh wave, the Rayleigh wave propagates to a surface 102a of the metal film 102. At this time, in a cross section of the vicinity of the surface 102a of the metal film 102, lattice points Q in the metal film 102 undergo an elliptical rotational motion. Incidentally, two circles C1 and C2 in the figure represent the orbits of two representative lattice points Q1 and Q2, respectively. This means that each lattice point Q in the metal film 102 has an angular momentum. The rotational frequency thereof reaches several GHz. The angular momentum is converted into electron spins in one direction (up spins or down spins) by the so-called Barnett effect in which a mechanical rotational motion is converted into electron spins according to the law of conservation of angular momentum. Generally, in a paramagnetic material, locally, the numbers of up spins and down spins of which the spin directions are opposite to each other are equal to each other. However, when the number of one electron spins increases, the state of equilibrium is disturbed, and a gradation in the concentration of the up spins and the down spins occurs. Namely, a region where one spins are more numerous than the other spins occurs. At this time, in order to maintain the state of equilibrium between the up spins and the down spins, the spins move in a direction in which the gradation in concentration is eliminated. The movement of the spins is a spin current. However, since no electric charge moves, no electric current flows.

The spin current generation in the present embodiment can be described similarly to the mechanism. When attention is paid to a very small region of the gradient layer 4, it can be considered that the electron velocity field or the electric current field (vector field) rotates due to a difference in electron movement velocity or electric current density (arrow Ar in the portion (b) in FIG. 5). The magnitude of the rotation Ar of the velocity field or the electric current field can also be understood as vorticity. Due to the rotation Ar of the velocity field or the electric current field, an angular momentum exists in the flow of a plurality of electrons in the gradient layer 4. Then, the angular momentum is converted into electron spins in one direction (up spins or down spins). Accordingly, a state of equilibrium between the up spins and the down spins is disturbed, thereby causing a bias in the relative distribution of the up spins and the down spins. As a result, a spin current is generated in a direction in which the bias in the distribution is eliminated (namely, a direction from the gradient layer 4 toward the metal layer 3).

As will be shown in examples to be described later, a spin current as large as or more than that based on spin orbit interaction (SOI) can be generated through the above-described action. In addition, the spin current generation based on the conventional SOI requires a special material such as a noble metal (for example, Pt) that generates SOI; however, the above-described action is realized simply by forming a gradient in the carrier mobility or the electrical conductivity, and does not require a special material such as Pt. Namely, by combining the metal layer made of any metal, for example, Al that exists abundantly in the earth's crust and a semiconductor layer made of any semiconductor, for example, Si that exists abundantly in the earth's crust, the gradient layer 4 having a gradient in the carrier mobility or the electrical conductivity can be easily formed. Therefore, a large spin current can be generated without excessively limiting the selection of materials to be used.

In addition, when the electrical conductivity of the spintronics device is low, there is a possibility that a problem such as a wiring delay or Joule loss in an integrated circuit arises. Further, the performance of a semiconductor device often deteriorates due to contamination by an element that generates SOI. Therefore, there is a demand for a spintronics device that has a high electrical conductivity and that does not depend on an element that generates SOI. In the device 1 of the present embodiment, since the metal layer 3 and the semiconductor layer 2 have a larger electrical conductance than oxides, the occurrence of a problem such as a wiring delay or Joule loss in an integrated circuit of a device such as a magnetic memory including the device 1 can be reduced.

As described above, the metal layer 3 may contain Al. Alternatively, the metal layer 3 may be an Al layer. Al is the third most abundant element after oxygen (O) and Si among elements that exist in the earth's crust, and is the most abundant element among metal elements. In addition, Al has a relatively high electrical conductance among the metal elements. Therefore, it is possible to provide a sustainable spintronics device capable of reducing electric power consumption.

As described above, the semiconductor layer 2 may contain Si. Alternatively, the semiconductor layer 2 may be a Si layer. Si is the second most abundant element after oxygen (O) among the elements that exist in the earth's crust, and is the most abundant element among elements constituting a semiconductor. Therefore, it is possible to provide a sustainable spintronics device.

When the metal layer 3 is an Al layer and the semiconductor layer 2 is a Si layer (namely, when the gradient layer 4 is made of Si and Al), the thickness of the gradient layer 4 may be 2.4 nm or less. According to experiments by the present inventors, by having such a thickness for the gradient layer 4, a larger spin current than a spin current generated by SOI can be generated.

As described above, one example of the method for manufacturing the device 1 according to the present embodiment includes the step of forming the first layer 4a by depositing the same material as the metal layer 3 on the semiconductor layer 2 through sputtering; the step of forming the second layer 4b by depositing the same material as the semiconductor layer 2 on the first layer 4a through sputtering; and the step of forming the metal layer 3 on the second layer 4b. In the manufacturing method, the gradient layer 4 is formed by mixing atoms of the first layer 4a and the second layer 4b in sputtering. Then, the thickness of the gradient layer 4 depends on the total thickness of the first layer 4a and the second layer 4b. Therefore, the gradient layer 4 of any thickness can be easily formed. In addition, the gradient layer 4 can also be formed, for example, by depositing the material of the semiconductor layer 2 and the material of the metal layer 3 at the same time, and gradually changing the deposition ratio thereof; however, in that case, a target made of the material of the semiconductor layer 2 and a target made of the material of the metal layer 3 should be installed in the sputtering apparatus at the same time, so that the size of the sputtering apparatus is increased. In the manufacturing method of the present embodiment, since the material of the semiconductor layer 2 and the material of the metal layer 3 are alternately deposited, the target made of the material of the semiconductor layer 2 and the target made of the material of the metal layer 3 may be alternately installed in the sputtering apparatus. Therefore, the number of the targets installed in the sputtering apparatus at the same time can be reduced, and the sputtering apparatus can be downsized.

### EXAMPLES

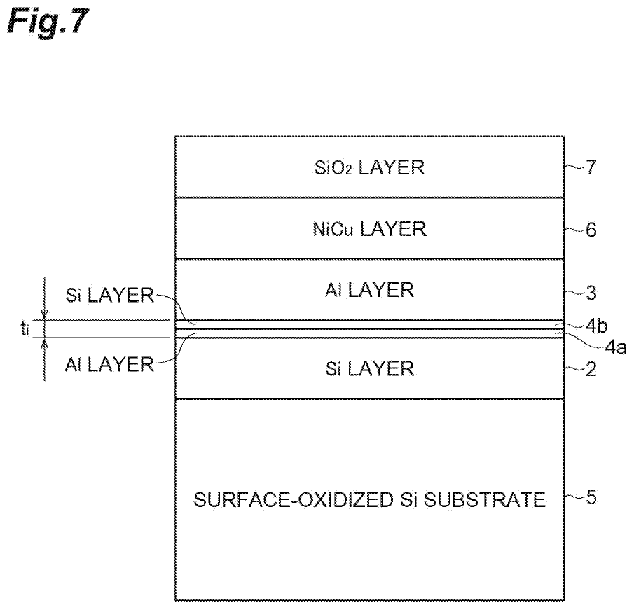

Experiments performed by the present inventors to confirm the above-described theory will be described. As shown in FIG. 7, the present inventors formed a Si layer (semiconductor layer 2: thickness 10 nm), an Al layer (first layer 4a: thickness (tᵢ/2) nm), a Si layer (second layer 4b: thickness (tᵢ/2) nm), an Al layer (metal layer 3: thickness 10 nm), a Ni_{0.95}Cu_{0.05} layer 6 (thickness 10 nm), and a SiO₂ layer 7 (thickness 20 nm) in order on a surface-oxidized Si substrate (substrate 5). Five samples were manufactured by changing the total thickness tᵢ of the first layer 4a and the second layer 4b from 0.0 nm to 2.0 nm at an interval of 0.5 nm. Incidentally, the total thickness tᵢ being set to 0.0 nm means that the first layer 4a and the second layer 4b are not formed.

Specifically, these layers were formed on the surface-oxidized Si substrate at room temperature by magnetron sputtering. The chamber base pressure was less than 2.0×10⁻⁴ Pa before these layers were deposited. The argon (Ar) pressure was 0.21 Pa, and the argon (Ar) flow rate was 4.0 sccm. For the generation of the Al layer, radio-frequency (RF) sputtering at 13.56 MHz was performed using a 99.9% pure Al target at an electric power density of 1.4 W/m² and a deposition rate of 0.043 nm/s. For the generation of the Si layer, RF sputtering at 13.56 MHz was performed using a non-doped Si target at an electric power density of 3.5 W/m² and a deposition rate of 0.062 nm/s. For the generation of the Ni_{0.95}Cu_{0.05} layer, direct current (DC) sputtering was performed using a 99.9% pure Ni_{0.95}Cu_{0.05} alloy target at an electric power density of 1.4 W/m² and a deposition rate of 0.2 nm/s. For the generation of the SiO₂ layer, RF sputtering at 13.56 MHz was performed using a 99.99% pure SiO₂ target at an electric power density of 3.5 W/m² and a deposition rate of 0.044 nm/s. Thereafter, strip-shaped samples having a width of 10 μm and a length of 100 μm were manufactured by performing photolithography and a lift-off process on a multilayer film consisting of these layers.

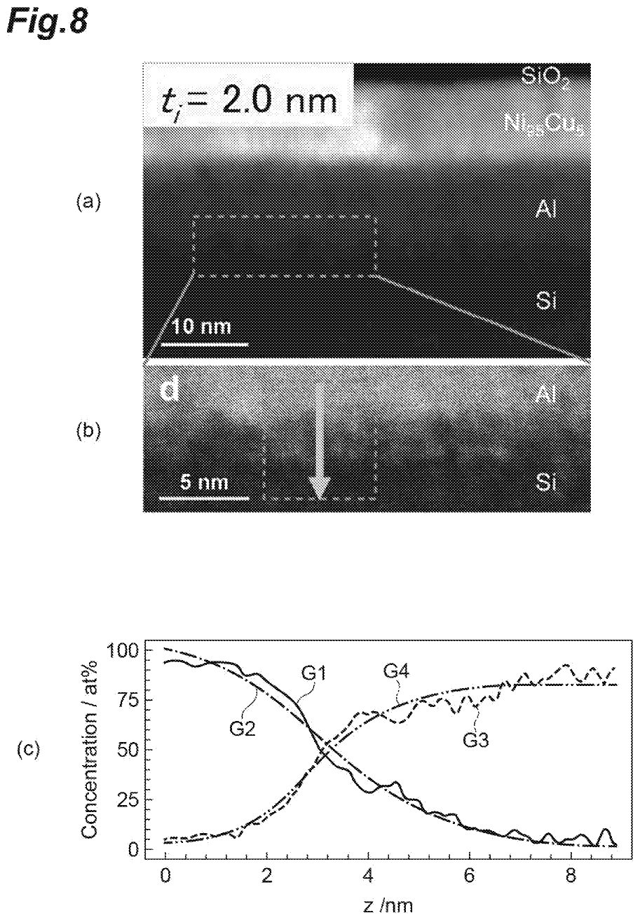

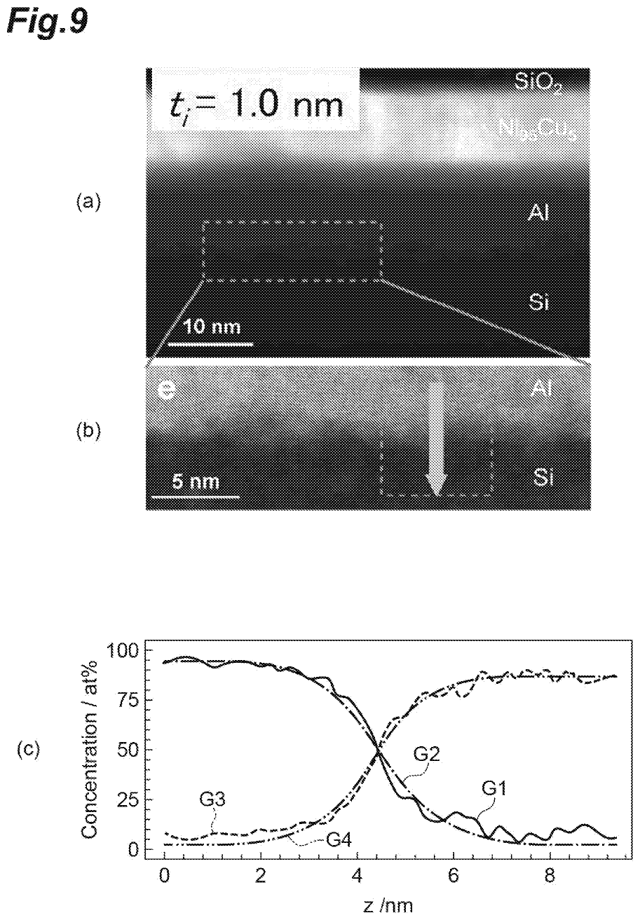

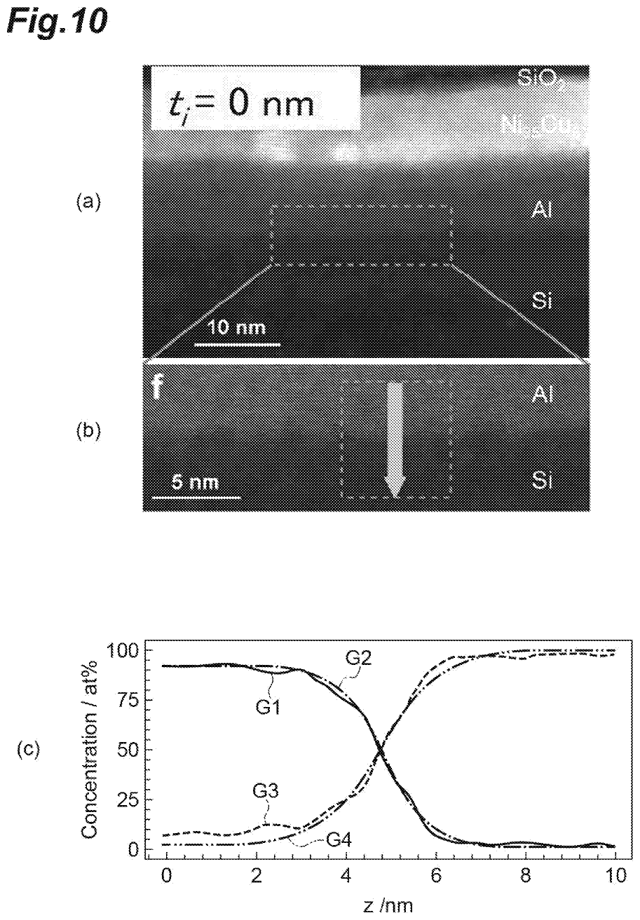

Portions (a) and (b) in FIGS. 8, 9, and 10 show layer structures of the manufactured samples, and are scanning transmission electron microscope (STEM) images obtained by the high-angle annular dark field (HAADF). The portion (a) in FIGS. 8, 9, and 10 shows a cross-sectional structure of the semiconductor layer 2 (Si layer), the metal layer 3 (Al layer), the Ni_{0.95}Cu_{0.05} layer 6, and the SiO₂ layer 7, and the portion (b) in FIGS. 8, 9, and 10 shows a boundary portion between the semiconductor layer 2 and the metal layer 3 in an enlarged manner. The portions (a) and (b) in FIG. 8 show when the total thickness tᵢ of the first layer 4a and the second layer 4b was set to 2.0 nm (namely, when the thickness tᵢ/2 of the first layer 4a and the thickness tᵢ/2 of the second layer 4b were each set to 1.0 nm). The portions (a) and (b) in FIG. 9 show when the total thickness t; of the first layer 4a and the second layer 4b was set to 1.0 nm (namely, when the thickness tᵢ/2 of the first layer 4a and the thickness tᵢ/2 of the second layer 4b were each set to 0.5 nm). The portions (a) and (b) in FIG. 10 show when the total thickness t₁ of the first layer 4a and the second layer 4b was set to 0.0 nm (namely, when the metal layer 3 was formed directly on the semiconductor layer 2 without forming the first layer 4a and the second layer 4b).

A portion (c) in FIGS. 8, 9, and 10 is a graph showing the distributions of the atomic concentrations of Si and Al obtained by performing energy dispersive X-ray spectroscopy (EDS) on regions inside broken line frames in the portion (b) in FIGS. 8, 9, and 10. In the graph of the portion (c), the horizontal axis represents the position in the thickness direction (nm), and the vertical axis represents the atomic concentration (atom %). In the portion (c), line G1 indicates the analysis result of the Al concentration, and line G2 indicates a function fitted to line G1. Line G3 indicates the analysis result of the Si concentration, and line G4 indicates a function fitted to line G3. The functions of lines G2 and G4 are expressed by the following formula (1).

### [Formula 1]

$$Composition = \frac{{C}_{1} + {C}_{2}}{2} \pm \frac{{C}_{2} - {C}_{1}}{2} tanh ( \frac{z - {z}_{int}}{L} )$$

Here, C₁ and C₂ are compositions at an upper end and a lower end of each broken line frame in the portion (b) respectively. z is a position in the thickness direction, and zᵢₙₜ is the center position of the boundary portion in the thickness direction. L is a thickness of a composition gradient from Si to Al (namely, the thickness of the gradient layer 4).

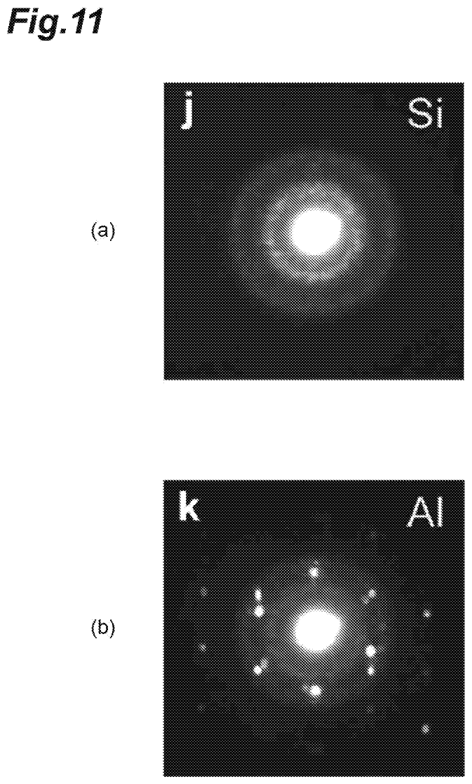

As shown in the portions (c) in FIGS. 8 and 9, it can be seen that the gradient layer 4 having a gentle composition gradient is suitably formed by forming the first layer 4a and the second layer 4b. As a result of an analysis, when the total thickness tᵢ of the first layer 4a and the second layer 4b was set to 2.0 nm, the thickness L of the gradient layer 4 was 2.4 nm. In addition, when the total thickness tᵢ of the first layer 4a and the second layer 4b was set to 1.0 nm, the thickness L of the gradient layer 4 was 1.3 nm. Incidentally, in the portion (c) in FIG. 10, a region with a gentle composition gradient is also formed; however, since the thickness L of the gradient layer 4 is 1.1 nm that is a value close to a lower limit of a spatial resolution, it is presumed that the thickness L of the gradient layer 4 is actually smaller than 1.1 nm, and a sharp interface is formed between Si and Al. Portions (a) and (b) in FIG. 11 are nano-beam electron diffraction (NBED) patterns for the semiconductor layer 2 (Si layer) and the metal layer 3 (Al layer) each having a thickness of 10 nm, respectively. It can be seen that the semiconductor layer 2 (Si layer) has an amorphous structure and the metal layer 3 (Al layer) has a polycrystalline structure.

Here, when an electric current is applied to a two-layer structure including a non-magnetic layer and a ferromagnetic layer, a part of a spin current generated in the non-magnetic layer moves toward the ferromagnetic layer, and a spin torque is applied to the magnetization of the ferromagnetic layer. The torque is referred to as a damping-like torque τ_{DL}. On the other hand, another spin torque known as a field-like torque τ_{FL} is generated from the spin current reflected at the interface between the non-magnetic layer and the ferromagnetic layer. The influence of these torques τ_{DL} and τ_{FL} on a magnetization m generated by a spin current having a polarization σₛ is described by the following formula (2).

### [Formula 2]

$$τ = {τ}_{DL} + {τ}_{FL} = {ξ}_{DL} {j}_{c} \frac{ℏ}{2 e} \frac{1}{{μ}_{0} {M}_{s} {d}_{FM}} m \times ( m \times {σ}_{s} ) + {ξ}_{FL} {j}_{c} \frac{ℏ}{2 e} \frac{1}{{μ}_{0} {M}_{s} {d}_{FM}} m \times {σ}_{s} \qquad ( 2 )$$

Here, ξ_{DL} and ξ_{FL} are the efficiencies of the damping-like torque and the field-like torque with respect to an electric current density j_{c}. e, μ₀, and h bar are an elementary electric charge, a vacuum permeability, and a normalized Planck's constant, respectively. Mₛ is a saturation magnetization, and d_{FM} is a thickness of the ferromagnetic layer.

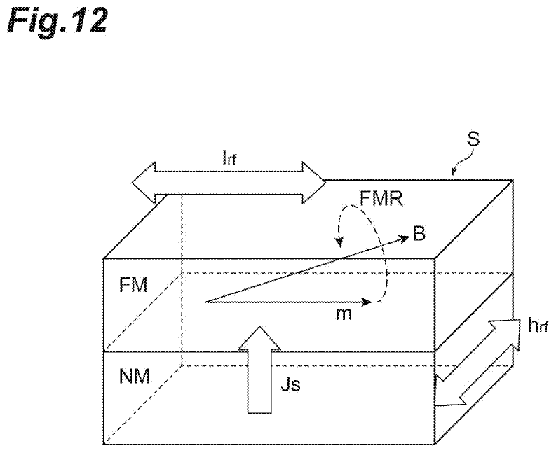

In the present example, spin torque ferromagnetic resonance (ST-FMR) measurement was performed to evaluate the strength of a spin torque generated by allowing an electric current to pass through a sample. FIG. 12 is a view for describing the principle of ST-FMR measurement. When an AC electric current I_{rf} is applied to a sample S including a non-magnetic layer NM and a ferromagnetic layer FM in a longitudinal direction, an AC magnetic field h_{rf} orthogonal to the AC electric current I_{rf} is generated. At the same time, spin accumulation occurs in a boundary region between the non-magnetic layer NM and the ferromagnetic layer FM due to a spin-hall effect (SHE). A spin current Jₛ due to the spin accumulation is injected into the ferromagnetic layer FM, and a spin torque ST acts on the magnetization m. Then, ferromagnetic resonance FMR that is the precession of the magnetization m is excited due to an external magnetic field B acting on the magnetization m of the ferromagnetic layer FM. The ST-FMR excitation generates a DC electric voltage in the same direction as the AC electric current I_{rf}. The strength of the spin torque can be determined by measuring a magnitude of the DC electric voltage.

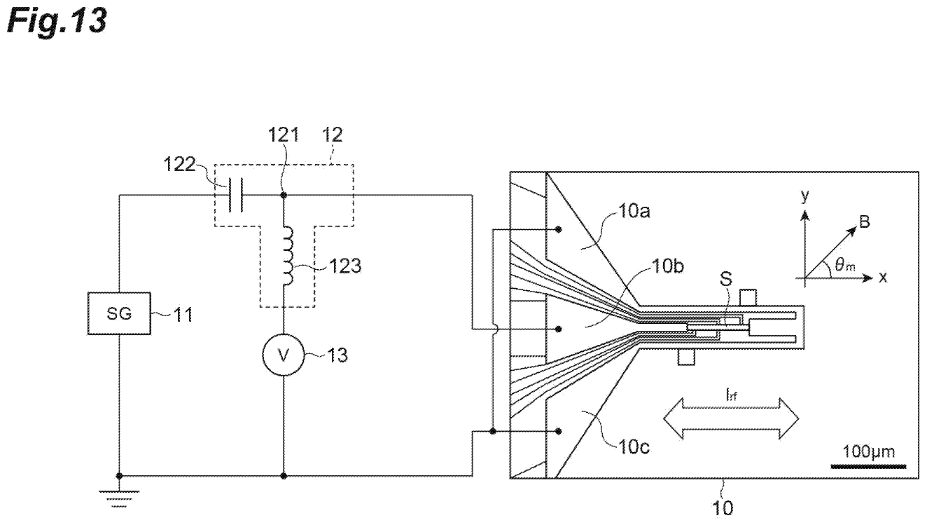

FIG. 13 is a view showing a circuit used for ST-FMR measurement. The circuit includes a substrate 10 on which the sample S is mounted, an AC electric current source 11, a bias tee circuit 12, and a voltmeter 13. Conductive films 10a to 10c each having a thickness of 70 nm and constituting a coplanar waveguide are formed on a surface of the substrate 10. The conductive films 10a to 10c are, for example, Au films. One end portions of the conductive films 10a to 10c are arranged in order along one side of the substrate 10. The other end portions of the conductive films 10a and 10c are electrically short-circuited to one end of the sample S in the longitudinal direction (x direction). The other end portion of the conductive film 10b is electrically short-circuited to the other end of the sample S in the longitudinal direction. The conductive films 10a and 10c are connected to a reference potential line (ground potential line) of the circuit. The conductive film 10b is connected to a node 121 of the bias tee circuit 12. The bias tee circuit 12 includes a capacitor 122 of which one end and the other end are connected to the node 121 and the AC electric current source 11, respectively, and an inductor 123 of which one end and the other end are connected to the node 121 and the voltmeter 13, respectively. The AC electric current source 11 are connected to the capacitor 122 at one end thereof and to the reference potential line (ground potential line) at the other end thereof, and supplies the AC electric current I_{rf} to the conductive film 10b via the capacitor 122. The voltmeter 13 are connected to the inductor 123 at one end thereof and to the reference potential line (ground potential line) at the other end thereof, and measures an electric voltage generated between the conductive film 10b and both the conductive films 10a and 10c. Incidentally, FIG. 13 shows an angle θₘ formed by the external magnetic field B and an orthogonal coordinate system consisting of the x direction that is the longitudinal direction of the sample S having a strip shape and a y direction that is a lateral direction of the sample S. Further, FIG. 13 shows an arrow indicating the AC electric current I_{rf}.

In the present example, microwaves having an electric power of 20 dBm and a frequency of 20 GHz were output from the AC electric current source 11 to apply the AC electric current I_{rf} to the sample. Then, a magnitude of the DC electric voltage was measured by the voltmeter 13 while sweeping the external magnetic field B between 0 T and 2.0 T. All measurements were performed at room temperature.

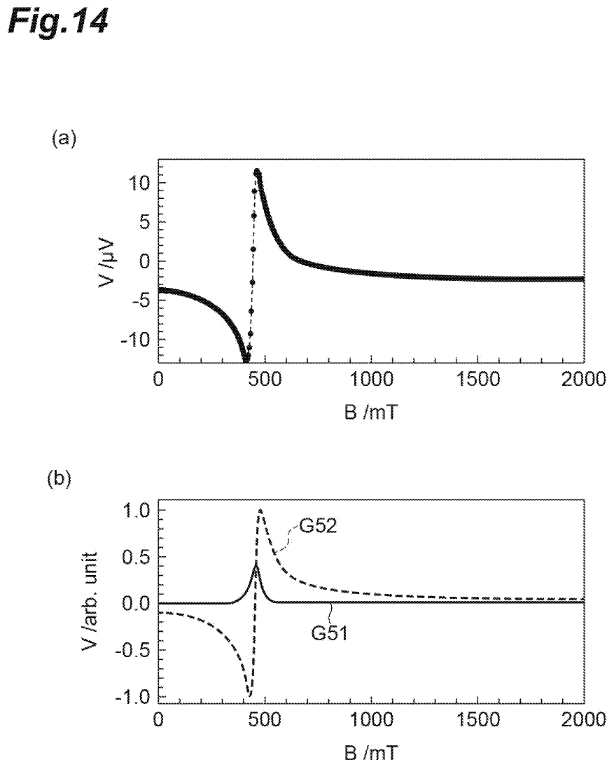

A portion (a) in FIG. 14 is a graph showing, as an example, an ST-FMR spectrum of the sample with tᵢ=0.5 nm measured in such a manner. In the portion (a) in FIG. 14, the horizontal axis represents the external magnetic field (mT), and the vertical axis represents the magnitude of the DC electric voltage (μV). A portion (b) in FIG. 14 shows symmetric (graph G51) and antisymmetric (graph G52) Lorentz function components included in the graph shown in the portion (a) in FIG. 11. Here, a spin torque efficiency ξ_{FMR}, which is generally used as an estimated value of ξ_{DL} when ξ_{FL} is negligible in ST-FMR, satisfies the following formula (3).

### [Formula 3]

$$\frac{1}{{ξ}_{FMR}} = \frac{1}{{ξ}_{DL}} ( 1 + \frac{ℏ}{e {μ}_{0} {M}_{s} {d}_{NM} {d}_{FM}} {ξ}_{FL} ) \qquad ( 3 )$$

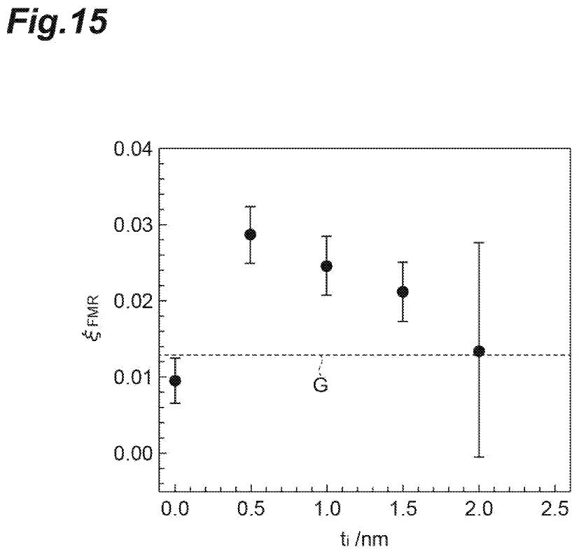

The spin torque efficiency ξ_{FMR} was evaluated based on an amplitude ratio Vs/Va between a symmetric Lorentz function component Vs and an antisymmetric Lorentz function component Va. As a result, for example, a spin torque efficiency of ξ_{FMR}=0.029 was obtained for the sample with tᵢ=0.5 nm, a spin torque efficiency of ξ_{FMR}=0.024 was obtained for the sample with tᵢ=1.0 nm, and a spin torque efficiency of ξ_{FMR}=0.013 was obtained for the sample with tᵢ=2.0 nm. FIG. 15 is a graph showing a relationship between the obtained spin torque efficiency ξ_{FMR} and the total thickness tᵢ of the first layer 4a and the second layer 4b. In FIG. 15, the horizontal axis represents the total thickness tᵢ (nm), and the vertical axis represents the spin torque efficiency ξ_{FMR} (more specifically, the standard deviation calculated from the least squares deviation of fitting parameters used in calculating ξ_{FMR}).

As shown in FIG. 15, the values of the spin torque efficiencies ξ_{FMR} of the samples with tᵢ=0.5 nm to 2.0 nm were larger than that of the spin torque efficiency ξ_{FMR} of a reference sample (broken line G in the figure) having a two-layer structure of an Al layer (10 nm) and a Ni₉₅Cu₅ layer (10 nm) manufactured on a surface-oxidized Si substrate. Particularly, in the range of tᵢ=0.5 nm to 2.0 nm, the smaller tᵢ was, the larger the spin torque efficiency ξ_{FMR} was. Incidentally, the spin torque efficiency ξ_{FMR} of the sample with tᵢ=0 nm, namely, in which the first layer 4a and the second layer 4b were not formed was smaller than the value (broken line G) of the reference sample. This result means that in the sample in which the first layer 4a and the second layer 4b are not formed (namely, without the gradient layer 4), most of a spin current is generated in the metal layer 3 through the spin-hall effect and the sharp Si—Al interface does not generate additional spin current. Namely, in the other samples, it can be said that the gradient of a nanometer thickness from the Si layer to the Al layer is the most important factor for spin current generation in the samples.

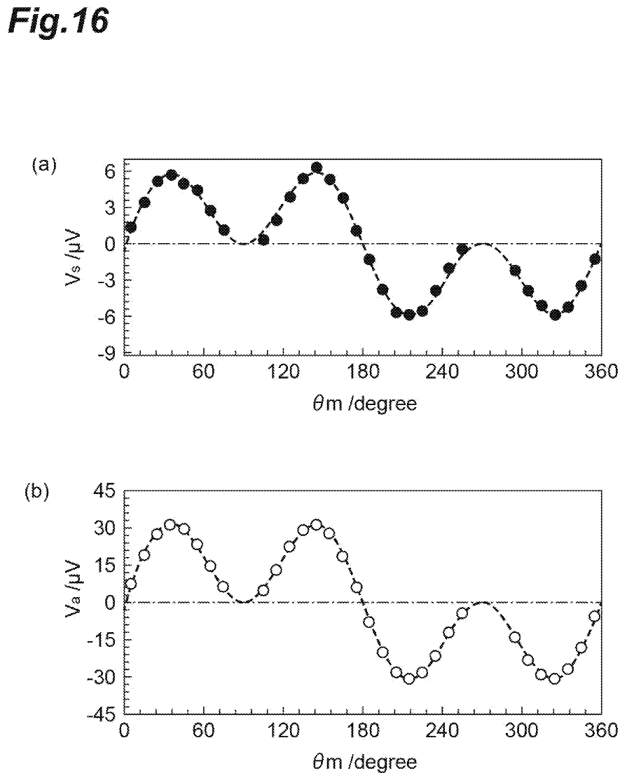

Incidentally, a portion (a) in FIG. 16 is a graph showing a relationship between the symmetric Lorentz function component Vs and the application angle θₘ of the external magnetic field B. In addition, a portion (b) in FIG. 16 is a graph showing a relationship between the antisymmetric Lorentz function component Va and the application angle θₘ of the external magnetic field B. From these graphs, it can be said that a spin current having the same spin polarization as the spin-hall effect due to bulk SOI is generated.

A large difference in electrical conductivity between the non-magnetic layer and the ferromagnetic layer means that the contribution of the field-like torque efficiency ξ_{FL} is not negligible. As shown in the above formula, both the damping-like torque efficiency ξ_{DL} and the field-like torque efficiency ξ_{FL} can be determined based on the spin torque efficiency ξ_{FMR} and the thickness dim of the ferromagnetic layer. Further, a ratio (ξ_{FL}/ξ_{DL}) between the damping-like torque efficiency ξ_{DL} and the field-like torque efficiency ξ_{FL} depends on the condition of the interface between the non-magnetic layer and the ferromagnetic layer, namely, the interface between the metal layer 3 (Al layer) and the Ni_{0.95}Cu_{0.05} layer 6. Therefore, the value of the ratio (ξ_{FL}/ξ_{DL}) is determined independently of the thickness L of the gradient layer 4 between the semiconductor layer 2 (Si layer) and the metal layer 3 (Al layer). In the present example, the ratio (ξ_{FL}/ξ_{DL}) was 3 based on the values of the damping-like torque efficiency ξ_{DL} and the field-like torque efficiency ξ_{FL} of the sample with tᵢ=1.0 nm.

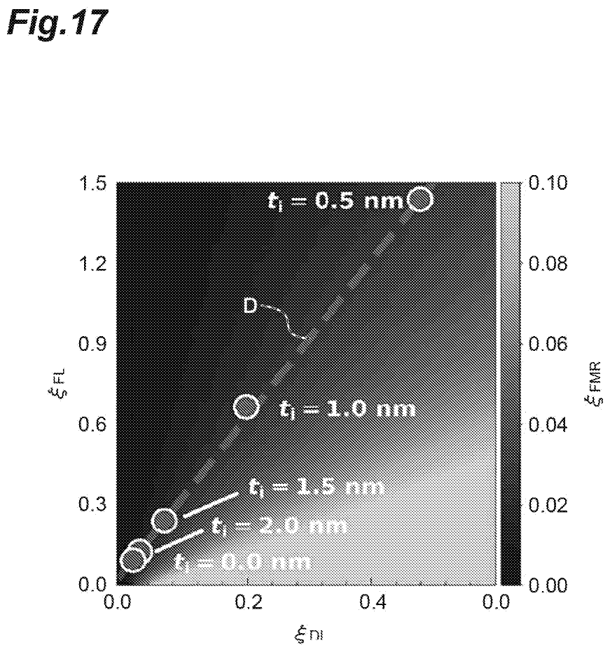

FIG. 17 is a graph showing a relationship between the spin torque efficiency ξ_{FMR} and both the damping-like torque efficiency SDI, and the field-like torque efficiency ξ_{FL}. In FIG. 17, the horizontal axis represents the damping-like torque efficiency ξ_{DL}, and the vertical axis represents the field-like torque efficiency ξ_{FL}. In addition, the spin torque efficiency ξ_{FMR} is shown in the gradation of a color. The darker the color is, the smaller the spin torque efficiency ξ_{FMR} is, and the lighter the color is, the larger the spin torque efficiency ξ_{FMR} is. In addition, a straight line D shown by a broken line in FIG. 17 indicates the condition ξ_{FL}/ξ_{DL}=3. Further, in FIG. 17, a plurality of plots corresponding to the samples with tᵢ=0.0 nm to 2.0 nm are shown at positions on the straight line D corresponding to the measured values of the spin torque efficiencies ξ_{FMR} of the samples (refer to FIG. 15).

As clear from FIG. 17, the magnitudes of the damping-like torque efficiency ξ_{DL} and the field-like torque efficiency ξ_{FL} increase with a reduction in the total thickness tᵢ of the first layer 4a and the second layer 4b. In other words, the magnitudes of the damping-like torque efficiency ξ_{DL} and the field-like torque efficiency ξ_{FL} increase with a reduction in the thickness L of the gradient layer 4. For example, the damping-like torque efficiency EDI, of the sample with tᵢ=1.0 nm reaches three times the magnitude of the damping-like torque efficiency ξ_{DL} of Pt. The damping-like torque efficiency ξ_{DL} of the sample with tᵢ=0.5 nm increases further therethan.

Incidentally, in the present example, the fact that the ratio (ξ_{FL}/ξ_{DL}) is 3 implies that a reflected spin current is three times a transmitted spin current. The reason is that an electrical conductivity of the Ni_{0.95}Cu_{0.05} layer 6 that is a side which absorbs the spin current is one order of magnitude smaller than an electrical conductivity of the metal layer 3 (Al layer) that is a side into which the spin current is injected. Therefore, the damping-like torque efficiency ξ_{DL} can be further increased by using a ferromagnetic material having a higher electrical conductivity than the Ni_{0.95}Cu_{0.05} layer 6.

As described above, a larger amount of spin current was generated in the samples with tᵢ=0.5 nm to 2.0 nm than in the sample with tᵢ=0.0 nm, and among the samples with tᵢ=0.5 nm to 2.0 nm, the smaller tᵢ was, the larger the amount of the generated spin current was. This strongly implies that a spin current is generated by the rotation of an electric current velocity field or an electric current field (spin vorticity coupling: SVC) caused by a change in the carrier mobility or electrical conductivity of the gradient layer 4 in the thickness direction. It is presumed that the magnitude of the spin current becomes maximum when the thickness of the gradient layer 4 is equal to an effective mean free path of electrons.

The contribution of SVC to spin current generation can also be described by strong non-reciprocity between electric current and spin current. Here, the non-reciprocity between electric current and spin current means that a conversion efficiency from an electric current to a spin current is significantly different from a conversion efficiency from a spin current to an electric current. When the spin current generation is a phenomenon based on SOI, the conversion efficiency from an electric current to a spin current is approximately equal to the conversion efficiency from a spin current to an electric current. On the other hand, when the spin current generation is a phenomenon based on SVC, a spin current cannot be converted into an electric current, so that the conversion efficiency from a spin current to an electric current is significantly smaller than the conversion efficiency from an electric current to a spin current.

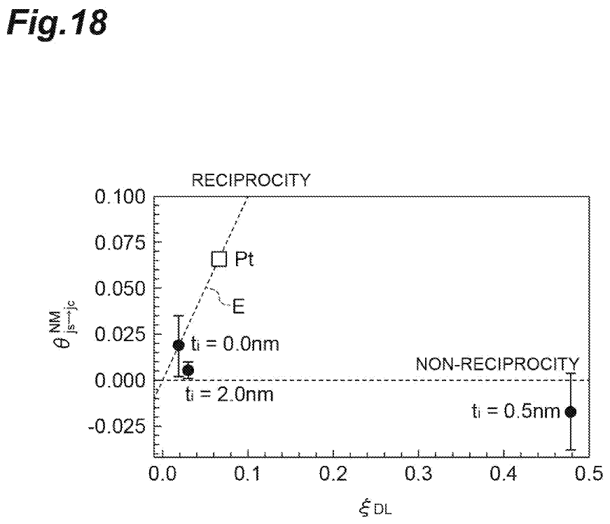

Therefore, in order to evaluate the conversion efficiency from a spin current to an electric current for the above-described samples, the inventors applied an AC magnetic field to the samples, and measured a magnitude of an inverse spin-hall effect due to the generated spin current. FIG. 18 is a graph showing a relationship between a conversion efficiency θ_{js→jc} from a spin current to an electric current and the damping-like torque efficiency ξ_{DL}. In the same figure, the horizontal axis represents the damping-like torque efficiency ξ_{DL}, and the vertical axis represents the conversion efficiency θ_{js→jc}. In the figure, plots corresponding to the samples with tᵢ of 0.0 nm, 0.5 nm, and 2.0 nm are shown. In addition, in the figure, as a reference example, a plot for a two-layer film made of Pt (thickness 10 nm) and Ni_{0.95}Cu_{0.05} (thickness 10 nm) is also shown. A line extending upward and downward from each plot indicates a standard deviation calculated from the least squares deviation of fitting parameters used to calculate ξ_{js→jc}.

As shown in FIG. 18, for the sample with tᵢ=0.0 nm and Pt, the plots exist on a straight line E in the figure, and it can be seen that the conversion efficiency θ_{js→jc} is proportional to the damping-like torque efficiency ξ_{DL}. This implies that in the samples with tᵢ=0.0 nm and Pt, a spin current is generated by SOI. On the other hand, the conversion efficiency θ_{js→jc} of each of the samples with tᵢ=0.5 nm to 2.0 nm exists near zero, and it can be seen that the conversion efficiency θ_{js→jc} is a very small value regardless of the damping-like torque efficiency ξ_{DL}. Namely, in the samples with tᵢ=0.5 nm to 2.0 nm, the electric current and the spin current have high non-reciprocity. This implies that SVC contributes to spin current generation in the samples with tᵢ=0.5 nm to 2.0 nm.

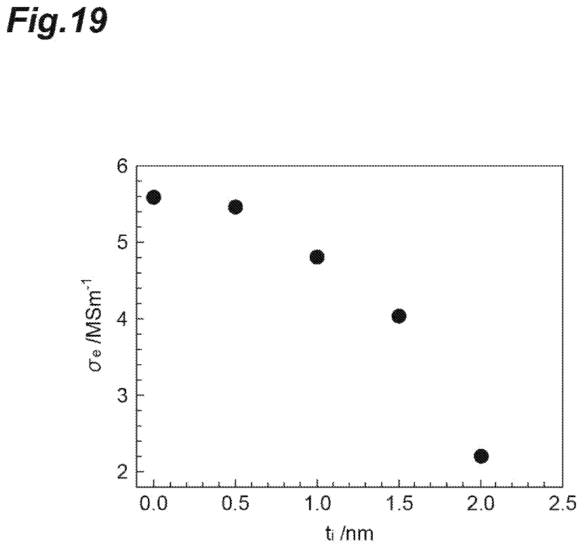

FIG. 19 is a graph showing a relationship between the total thickness tᵢ of the first layer 4a and the second layer 4b and an electrical conductance σₑ of the samples. In the same figure, the horizontal axis represents the total thickness tᵢ (nm), and the vertical axis represents the electrical conductance σₑ (MSm⁻¹). As shown in the same figure, the electrical conductance σₑ of the sample when the total thickness tᵢ is 0.0 nm (namely, when the first layer 4a and the second layer 4b are not formed) is at its highest; however, it can be seen that in the samples with a total thickness tᵢ of 0.5 nm to 2.0 nm, the smaller the total thickness tᵢ is, the higher the electrical conductance σₑ of the samples becomes, and the electrical conductance σₑ when the total thickness tᵢ is 0.5 nm is comparable to the electrical conductance σₑ when the first layer 4a and the second layer 4b are not formed. As described above, in the samples with tᵢ=0.5 nm to 2.0 nm, the smaller tᵢ is, the larger the damping-like torque efficiency ξ_{DL} is. Therefore, this result indicates that the electrical conductance σₑ increases with an increase in the damping-like torque efficiency ξ_{DL}, and shows a property opposite to that of a material that generates a spin current through SOI. From this fact, it can be seen that the spin current generation in the present embodiment is due to SVC rather than SOI.

In addition, from the viewpoint of reducing the applied electric voltage required for magnetic switching by a spin torque, it is desirable that the value of a product of the damping-like torque efficiency ξ_{DL} and the electrical conductance σₑ of the ferromagnetic material is large. In addition, in order to reduce the resistance-capacitance delay that hinders high-speed operation of the integrated circuit, it is desirable that the electrical conductance of itself is large. Therefore, ξ_{DL}·σₑ² is defined as a performance index.

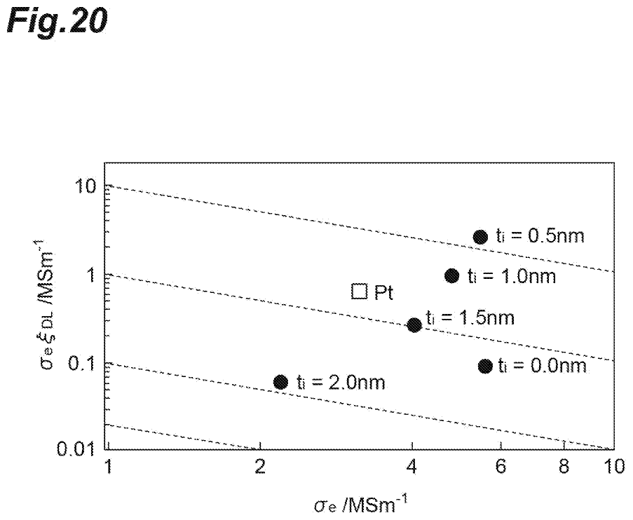

FIG. 20 is a graph showing a relationship between the electrical conductance σₑ and a product ξ_{DL}·σₑ of the damping-like torque efficiency ξ_{DL} and the electrical conductance σₑ for each sample. In the same figure, the horizontal axis represents the electrical conductance σₑ (unit: MSm⁻¹) in logarithm, and the vertical axis represents the product ξ_{DL}·σₑ (unit: MSm⁻¹) in logarithm. In the figure, plots for the samples with tᵢ=0.0 nm to 2.0 nm (black circles in the figure) and a plot for the two-layer film made of Pt and NiCu (white square in the figure) are shown. In addition, in the figure, isolines for the performance index ξ_{DL}·σₑ² are shown by broken lines. Referring to FIG. 20, the performance index of the sample with tᵢ=1.0 nm exceeds that of the two-layer film made of Pt and NiCu, and the performance index of the sample with tᵢ=1.0 nm reaches nearly 10 times that of the two-layer film made of Pt and NiCu. In such a manner, the device 1 including the gradient layer 4 made of Al and Si has the potential to greatly exceed Pt, which is a representative SOI material, in terms of the performance index that takes into account the applied electric voltage required for magnetic switching and the electrical conductance. Namely, the spintronics device that generates a spin current based on SVC using the gradient layer 4 can operate at high speed and reduce electric power consumption compared to the case of generating a spin current based on SOI.

### Second Embodiment

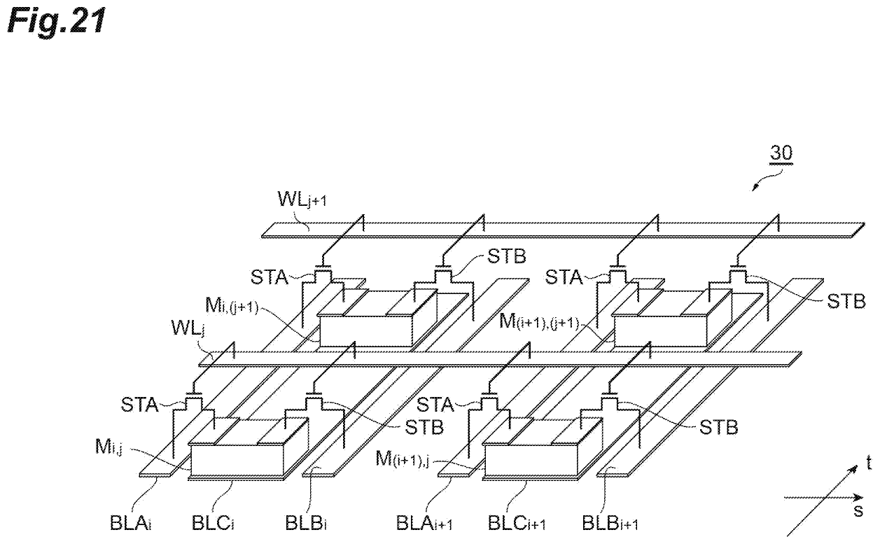

FIG. 21 is a perspective view showing a configuration of a magnetic memory 30 according to a second embodiment of the present disclosure. The magnetic memory 30 is a magnetic random access memory, and includes the device 1 according to the first embodiment. Specifically, the magnetic memory 30 includes memory cells M_{1,1} to M_{I,J} arranged in a matrix pattern in a row direction (s direction) and a column direction (t direction). Incidentally, in the figure, the memory cells M_{i,j}, M_{i,(j+1}), M_{(i+1),j}, and M_{(i+1),(j+1)} are representatively shown (i=1, 2, . . . , I−1, and j=1, 2, . . . , J−1).

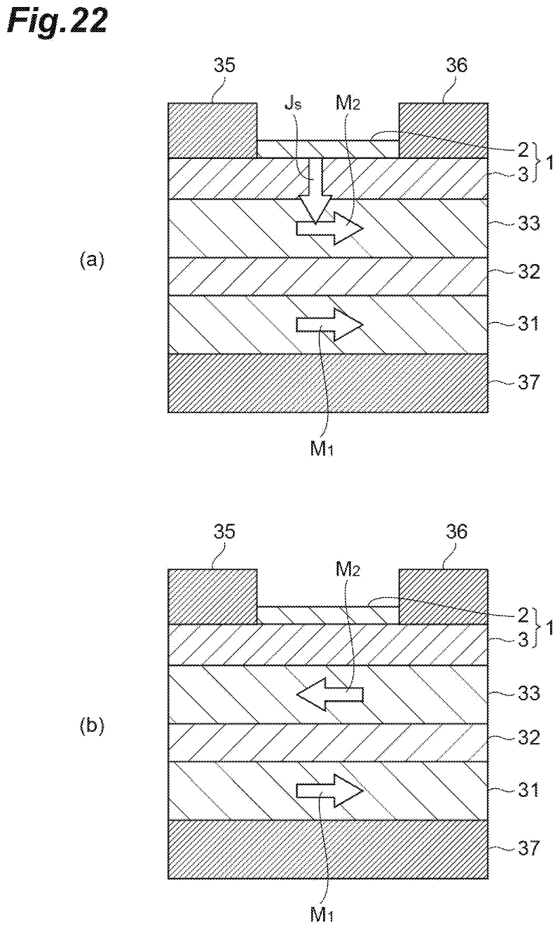

A portion (a) in FIG. 22 is a cross-sectional view showing a configuration of the memory cell M_{i,j}. The memory cell M_{i,j} is a giant magnetoresistance (GMR) cell or a tunnel magnetoresistance (TMR) cell, and includes a first ferromagnetic layer (fixed layer) 31; a non-magnetic layer 32 provided on the ferromagnetic layer 31; a second ferromagnetic layer (movable layer) 33 provided on the non-magnetic layer 32; and the device 1 provided on the ferromagnetic layer 33. The device 1 has the same configuration as that in the first embodiment. Namely, the device 1 includes the metal layer 3 provided on the ferromagnetic layer 33; the semiconductor layer 2 provided on the metal layer 3; and the gradient layer 4 (not shown) formed between the metal layer 3 and the semiconductor layer 2. The configurations of the semiconductor layer 2 and the metal layer 3 are same as those in the first embodiment, and the carrier mobility or electrical conductivity of the semiconductor layer 2 is lower than the carrier mobility or electrical conductivity of the metal layer 3. The gradient layer 4 located at the boundary between the metal layer 3 and the semiconductor layer 2 has a gradient in the carrier mobility or the electrical conductivity in the stacking direction. A spin current is generated in the device 1 due to the rotation of an electron velocity field or an electric current field caused by the gradient in the carrier mobility or the electrical conductivity. A pair of electrodes 35 and 36 are disposed on the metal layer 3. The electrodes 35 and 36 are arranged spaced apart from each other. An electrode 37 is disposed below the ferromagnetic layer 31.

Incidentally, the other memory cells M_{i,(j+1)}, M_{(i+1),j}, and M_{(i+1),(j+1)} shown in FIG. 21 are also GMR cells or TMR cells having the same configuration as the memory cell M_{i,j} shown in the portion (a) in FIG. 22.

Information corresponding to directions of relative magnetizations M₁ and M₂ of the ferromagnetic layers 31 and 33 is stored in the memory cell M_{i,j} shown in the portion (a) in FIG. 22. For example, NiFe is adopted as the material of the ferromagnetic layers 31 and 33. The ferromagnetic layers 31 and 33 may be made of different materials or may be made of the same material. The magnetization M₁ of the ferromagnetic layer 31 is fixed, and the magnetization M₂ of the ferromagnetic layer 33 is variable. As the material of the non-magnetic layer 32, in addition to non-magnetic metal such as Cu, for example, insulators such as aluminum oxide (Al₂O₃) and magnesium oxide (MgO) can also be used.

Referring again to FIG. 21, a word line WLⱼ is disposed in a j-th row, and a word line WLⱼ₊₁ is disposed in a (j+1)-th row. Three bit lines BLAᵢ, BLBᵢ, and BLCᵢ are disposed in an i-th column, and three bit lines BLAᵢ₊₁, BLBᵢ₊₁, and BLCᵢ₊₁ are disposed in an (i+1)-th column. In such a manner, at least one word line is disposed for each row, and at least three bit lines are disposed for each column. In addition, a pair of selection transistors STA and STB are connected to each of the memory cells M_{i,j}, M_{i,(j+1)}, M_{(i+1),j} and M_{(i+1),(j+1)}. One electric current terminal of the selection transistor STA is connected to the electrode 35, and one electric current terminal of the selection transistor STB is connected to the electrode 36. The other electric current terminals of the selection transistors STA and STB connected to the memory cells M_{i,j} and M_{i,(j+1)} in the i-th column are connected to the bit lines BLAᵢ and BLBᵢ, respectively. The other electric current terminals of the selection transistors STA and STB connected to the memory cells M_{(i+1),j} and M_{(i+1),(j+1)} in the (i+1)-th column are connected to the bit lines BLAᵢ₊₁ and BLBᵢ₊₁, respectively. Control terminals of the selection transistors STA and STB connected to the memory cells M_{i,j} and M_{(i+1),j} in the j-th row are connected to the word line WLⱼ. The control terminals of the selection transistors STA and STB connected to the memory cells M_{i,(j+1)}, and M_{(i+1),(j+1)} in the (j+1)-th row are connected to the word line WLⱼ₊₁.

In addition, the electrode 37 of the memory cells M_{i,j} and M_{i,(j+1)} in the i-th column is connected to the bit line BLCᵢ. The electrode 37 of the memory cells M_{(i+1),j} and M_{(i+1),(j+1)} in the (i+1)-th column are connected to the bit line BLCᵢ₊₁. The word lines WLⱼ and WLⱼ₊₁ and the bit lines BLAᵢ, BLAᵢ₊₁, BLBᵢ, BLBᵢ₊₁, BLCᵢ, and BLCᵢ₊₁ are connected to a control circuit (not shown).

During writing to the memory cells M_{i,j}, M_{i,(j+1)}, M_{(i+1),j}, and M_{(i+1),(j+1)}, by turning on the selection transistors STA and STB of the row through the word line WLⱼ corresponding to the selected memory cell (here, the memory cell M_{i,j}) and allowing an electric current to flow between the electrode 35 and the electrode 36 through the bit lines BLAᵢ and BLBᵢ of the column, the spin current Jₛ is generated in the device 1 of the memory cell M_{i,j}. The spin current Jₛ interacts with the magnetization M₂ of the ferromagnetic layer 33, and the transfer of a spin angular momentum to the magnetization M₂ occurs. As a result, the magnetization M₂ of the ferromagnetic layer 33 is reversed.

The memory cells M_{i,j}, M_{i,(j+1)}, M_{(i+1),j}, and M_{(i+1),(j+1)} read out information using a GMR effect or a TMR effect. Namely, the selection transistors STA and STB of the row are turned on through the word line WLⱼ corresponding to the selected memory cell (here, the memory cell M_{i,j}), and an electric current is allowed to flow between the electrodes 35 and 36 and the electrode 37 through the bit lines BLAᵢ, BLBᵢ, and BLCᵢ of the column. As shown in the portion (a) in FIG. 22, when the magnetizations of the ferromagnetic layers 31 and 33 are in a parallel state, an electric current path in a vertical direction passing through the ferromagnetic layer 31, the non-magnetic layer 32, and the ferromagnetic layer 33 has a relatively low resistance, and, for example, “1” is read out via the bit lines BLAᵢ, BLBᵢ, and BLCᵢ. On the other hand, as shown in a portion (b) in FIG. 22, when the direction of the magnetization of the ferromagnetic layer 33 is reversed, and the magnetizations of the ferromagnetic layers 31 and 33 are in an anti-parallel state, the electric current path in the vertical direction passing through the ferromagnetic layer 31, the non-magnetic layer 32, and the ferromagnetic layer 33 has a relatively high resistance, and, for example, “0” is read out via the bit lines BLAᵢ, BLBᵢ, and BLCᵢ.

According to the magnetic memory 30 of the present embodiment, a spin current is generated by the device 1 capable of generating a spin current without depending on a specific material, and the spin current interacts with the magnetization of the ferromagnetic layer 33, thereby being able to control the magnetization direction of the ferromagnetic layer 33.

In addition, the magnetic memory 30 of the present embodiment can be applied to various electronic apparatuses. Namely, one or more magnetic memories 30 may be mounted on the electronic apparatus. Examples of the electronic apparatus include apparatuses requiring a memory, such as a memory board on which a plurality of the magnetic memories 30 are mounted, an electronic component on which a plurality of the magnetic memories 30 or memory boards are mounted, a home appliance on which the magnetic memory 30, a memory board, or an electronic component is mounted, a personal computer, a smartphone, an in-vehicle apparatus, a measuring apparatus, and a control apparatus.

In addition, according to the magnetic memory 30 of the present embodiment, the following new effects can be achieved.

The efficiency of spin current generation due to the spin-hall effect resulting from spin orbit interaction (SOI) is expressed as a spin hall conductivity σ_{SH}. An electric current density is obtained by multiplying an electric voltage V by the electrical conductivity σ (Ohm's law), and similarly, a spin current density is obtained by multiplying the electric voltage V by the spin hall conductivity σ_{SH}. The larger the spin hall conductivity σ_{SH} is, the smaller the electric voltage V for generating a spin current necessary to rewrite bits of the magnetic memory becomes. Since energy consumption for rewriting bits is proportional to the square of the electric voltage V, the larger the spin hall conductivity σ_{SH} is, the smaller the energy consumption for rewriting bits can be made.

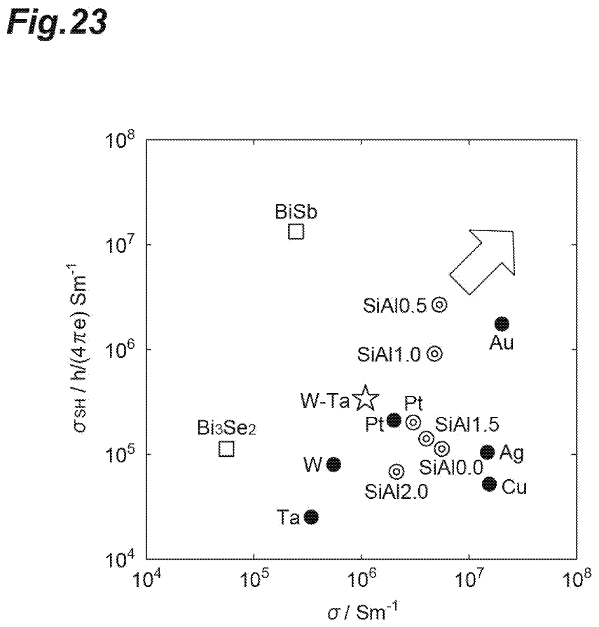

Here, FIG. 23 is a graph that plots various materials according to the spin hall conductivity σ_{SH} and the electrical conductivity σ. In FIG. 23, the vertical axis represents a value (unit: Sm⁻¹) obtained by dividing the spin hall conductivity σ_{SH} by h/(4πe) (h is a Planck's constant and e is an elementary electric charge amount), and the horizontal axis represents the electrical conductivity σ (unit: Sm⁻¹). As shown in FIG. 23, generally, in metal such as Cu or Ag that has large electrical conductivity σ, the spin hall conductivity σ_{SH} is small. In addition, the electrical conductivity σ of a topological insulator such as BiSb that has large spin hall conductivity σ_{SH} is small. When a material having small electrical conductivity σ is used as a spin current generation source of the magnetic memory, the wiring resistance of each bit of the magnetic memory increases, and signal delay and attenuation, signal waveform deformation, an increase in electric power consumption, electromagnetic wave radiation, and the like occur, so that a high-speed and electric power-saving operation is hindered. On the other hand, in the present embodiment, by performing spin current generation based on a completely new principle, a large spin current can be generated using a material such as AlSi that has large electrical conductivity σ but has small spin hall conductivity σ_{SH} inherent to the substance. FIG. 23 shows plots corresponding to the samples with tᵢ=0.0 nm to 2.0 nm (labeled as SiAl0.0, SiAl0.5, SiAl1.0, SiAl1.5, and SiAl2.0 in the figure, respectively).

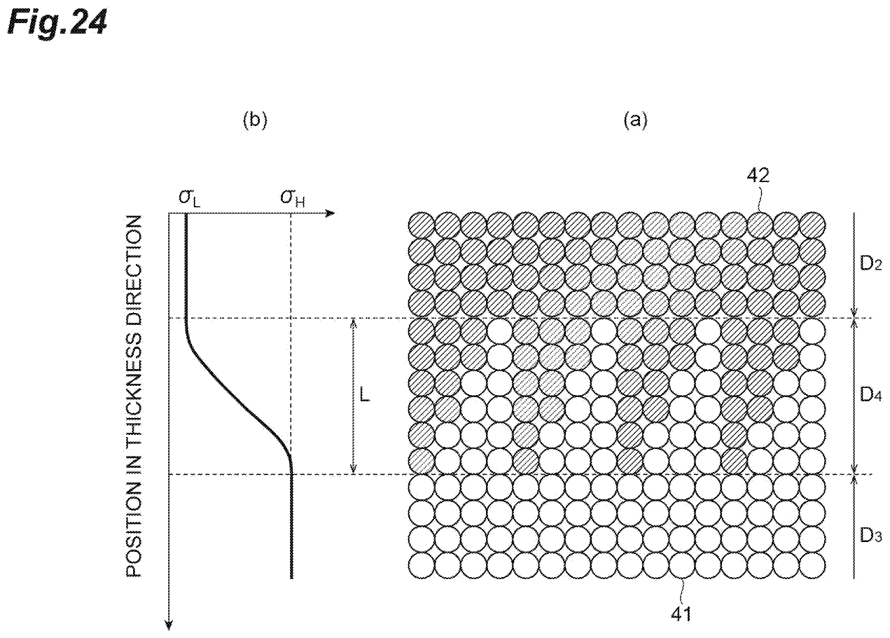

A portion (a) in FIG. 24 is a view schematically showing an atomic structure of the semiconductor layer 2, the metal layer 3, and the gradient layer 4. In the same figure, the range D₂ corresponds to the semiconductor layer 2, the range D₃ corresponds to the metal layer 3, and the range D₄ corresponds to the gradient layer 4. In addition, in the same figure, atoms 41 constituting the metal layer 3 and atoms 42 constituting the semiconductor layer 2 are schematically shown. As shown in the same figure, in the gradient layer 4, the atoms 41 constituting the metal layer 3 and the atoms 42 constituting the semiconductor layer 2 are mutually diffused. The closer the atoms are to the metal layer 3, the higher the proportion of the atoms 41 becomes, and the closer the atoms are to the semiconductor layer 2, the higher the proportion of the atoms 42 becomes. A portion (b) in FIG. 24 is a graph showing a change in the electrical conductivity σ in the thickness direction, the horizontal axis represents the electrical conductivity σ, and the vertical axis represents the position in the thickness direction corresponding to the portion (a).

As shown in the portion (b) in FIG. 24, by creating a composition gradient at the boundary between different substances, the electrical conductivity σ is gradually changed over the thickness L from on (maximum electrical conductivity) to σ_{L} (minimum electrical conductivity and σ_{H}>σ_{L}). Incidentally, typically, the maximum electrical conductivity σ_{H} is the electrical conductivity of the metal layer 3, and the minimum electrical conductivity σ_{L} is the electrical conductivity of the semiconductor layer 2. In this case, since the electrical conductivity at the center of the gradient layer 4 is given by an average value (σ_{H}+σ_{L})/2 of the maximum electrical conductivity σ_{H} and the minimum electrical conductivity σ_{L}, if σ_{H} is sufficiently larger than σ_{L}, the electrical conductivity can be approximated to σ_{H}/2. On the other hand, the spin hall conductivity σ_{SH} of the spin current generated by an electric current vortex in the gradient layer 4 is given by the following formula (4) based on theoretical calculations.

### [Formula 4]

$${σ}_{SH} = 0.05 \cdot {σ}_{H} \cdot {( \frac{l}{Lh} )}^{2} \qquad ( 4 )$$

Here, l is a mean free path (collision distance) of electrons flowing through the gradient layer 4. In addition, Lh=L/2 (L is the thickness of the gradient layer 4). As clear from this formula, the spin hall conductivity σ_{SH} of the gradient layer 4 is proportional to σ_{H}. This indicates that a large spin current can be generated using a material having large electrical conductivity σ, regardless of the spin hall conductivity σ_{SH} inherent to the various materials shown in FIG. 23. Further, in the above formula (4), the spin hall conductivity σ_{SH} is inversely proportional to the square of Lh. Namely, the spin hall conductivity σ_{SH} is inversely proportional to the square of the thickness L of the gradient layer 4. Therefore, by reducing the thickness L, the efficiency of spin current generation can be improved without changing the material system of the semiconductor layer 2 and the metal layer 3. From the above description, according to the magnetic memory 30 of the present embodiment that generates a spin current through the rotation of the electron velocity field or the electric current field caused by the gradient of the gradient layer 4 having a gradient in the carrier mobility or the electrical conductivity, compared to a conventional magnetic memory, the wiring resistance of each bit can be significantly reduced, and signal delay and attenuation, signal waveform deformation, an increase in electric power consumption, and electromagnetic wave radiation, and the like can be suppressed.

The spintronics device, the magnetic memory, and the electronic apparatus according to the present invention are not limited to the embodiments described above, and various other modifications can be made. For example, in the embodiments, Al has been provided as an example of the constituent material of the metal layer 3, and Si has been provided as an example of the constituent material of the semiconductor layer 2; however, the metal layer 3 may be made of metals other than Al, and the semiconductor layer 2 may be made of a semiconductor other than Si.

In addition, the preferred embodiments of the present invention have been described in detail; however, the present invention is not limited to the specific embodiments Namely, merely some of many possible embodiments of the present invention have been described, and it goes without saying that various modifications and changes can be made within the scope where the objects, tasks, or effects of the present invention are achieved, even if the various modifications and changes are not directly described in the embodiments. Particularly, the combination of a plurality of the components or functions described in the embodiments can be changed (added or deleted).

In addition, the tasks and objects of the present invention have been comprehensively described in the section “Technical Problem”, but are not limited thereto, and it goes without saying that the tasks and objects described in the embodiments are also valid for each invention. In addition, since the effects described in the embodiments are the opposite of the tasks or objects, the existence thereof should be understood even if the tasks or objects are not directly described.

In addition, the invention for achieving the tasks or objects is described in the embodiments; however, the level of achievement thereof does not necessarily need to be 100%, and changes depending on a combination of the configurations of the invention, and it goes without saying that the invention should not be denied as not achieving the objects, for example, even if the level of achievement is 10%.

### REFERENCE SIGNS LIST

1: spintronics device, 2: semiconductor layer, 3: metal layer, 4: gradient layer, 4a: first layer, 4b: second layer, 5: substrate, 6: Ni_{0.95}Cu_{0.05} layer, 7: SiO₂ layer, 9: heat treatment apparatus, 10: substrate, 11: AC electric current source, 12: bias tee circuit, 13: voltmeter, 30: magnetic memory, 31: ferromagnetic layer, 32: non-magnetic layer, 33: ferromagnetic layer, 35, 36, 37: electrode, 10a to 10c: conductive films, 102a: surface, 121: node, 122: capacitor, 123: inductor, B: external magnetic field, FM: ferromagnetic layer, Jₛ: spin current, m: magnetization, FMR: ferromagnetic resonance, NM: non-magnetic layer, Q: lattice point, S: sample, STA, STB: selection transistor, θₘ: application angle of external magnetic field.

1. A spintronics device that generates a spin current, the device comprising:
a metal layer;
a semiconductor layer having a lower carrier mobility or a lower electrical conductivity than the metal layer; and
a gradient layer located at a boundary between the metal layer and the semiconductor layer, and having a gradient in the carrier mobility or the electrical conductivity.

2. The spintronics device according to claim 1,
wherein the metal layer contains A₁.

3. The spintronics device according to claim 1,
wherein the metal layer is an Al layer.

4. The spintronics device according to claim 1,
wherein the semiconductor layer contains Si.

5. The spintronics device according to claim 1,
wherein the semiconductor layer is a Si layer.

6. The spintronics device according to claim 1,
wherein the metal layer is an Al layer, the semiconductor layer is a Si layer, and a thickness of the gradient layer is 2.4 nm or less.

7. The spintronics device according to claim 1,
wherein the spin current is generated by a rotation of an electron velocity field or an electric current field caused by the gradient.

8. The spintronics device according to claim 7,
wherein the spin current is generated by an angular momentum due to the rotation of the electron velocity field or the electric current field.

9. A magnetic memory comprising:
the spintronics device according to claim 1.

10. A magnetic memory comprising:
a first ferromagnetic layer;
a non-magnetic layer provided on the first ferromagnetic layer;
a second ferromagnetic layer provided on the non-magnetic layer;
a metal layer provided on the second ferromagnetic layer;
a semiconductor layer having a lower carrier mobility or a lower electrical conductivity than the metal layer, and provided on the metal layer; and
a gradient layer located at a boundary between the metal layer and the semiconductor layer, and having a gradient in the carrier mobility or the electrical conductivity,
wherein the magnetic memory stores information by controlling a direction of a magnetization of the second ferromagnetic layer using a spin current generated in the gradient layer.

11. An electronic apparatus,
wherein one or more magnetic memories according to claim 9 are mounted on the electronic apparatus.

12. A method for manufacturing the spintronics device according to claim 1, the method comprising:
forming a first layer by depositing a same material as the metal layer on the semiconductor layer through sputtering;
forming a second layer by depositing a same material as the semiconductor layer on the first layer through sputtering; and
forming the metal layer on the second layer.

13. An electronic apparatus,
wherein one or more magnetic memories according to claim 10 are mounted on the electronic apparatus.
